(19) United States
(12) Patent Application Publication
(10) Pub. No.: US 2026/0305394 A1
(43) Pub. Date: Oct. 1, 2026

(54) SEMICONDUCTOR STRUCTURE AND METHODS OF MANUFACTURING THE SAME

(71) Applicants: Taiwan Semiconductor Manufacturing Company, Ltd., Hsinchu (TW); TSMC Arizona Corporation, Phoenix, AZ (US)

(72) Inventors: Xuewen Tang, Hsinchu (TW); Ji-Feng Ying, Hsinchu City (TW); Wen-Hsien CHUANG, Taipei City (TW); Kuo-Hsiang Hsu, Taoyuan City (TW)

(73) Assignees: Taiwan Semiconductor Manufacturing Company, Ltd., Hsinchu (TW); TSMC Arizona Corporation, Phoenix, AZ (US)

(21) Appl. No.: 19/094,987

(22) Filed: Mar. 30, 2025

(51) Int. Cl. H01L 23/538; H01L 21/48; H01L 23/00; H01L 23/15; H01L 25/00; H01L 25/03

(52) U.S. Cl. CPC H10W 70/611; H10W 70/095; H10W 70/635; H10W 90/00; H10W 70/692; H10W 72/07353; H10W 72/334; H10W 90/734

(57) ABSTRACT

A semiconductor structure includes a substrate, a semiconductor device, a plurality of conductive pillars, a first redistribution circuit structure, and a semiconductor die. The substrate includes a first sub-layer and a second sub-layer disposed thereon. The semiconductor device is disposed in the second sub-layer and over the first sub-layer. The plurality of conductive pillars penetrate through the substrate and is next to the semiconductor device. The first redistribution circuit structure is disposed over the substrate and electrically coupled to the semiconductor device and the plurality of conductive pillars. The semiconductor die is disposed over and electrically coupled to the first redistribution circuit structure and electrically coupled to the semiconductor device through the first redistribution circuit structure, where the first redistribution circuit structure is disposed between the semiconductor die and the substrate.

### BACKGROUND

Developments in shrinking sizes of semiconductor devices and electronic components make the integration of more devices and components into a given volume possible and lead to high integration density of various semiconductor devices and/or electronic components. Integrated circuit applications currently have increasingly more functions built therein, and are thus formed to be increasingly larger.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 21 are schematic cross-sectional views of various stages in manufacturing a semiconductor structure in accordance with some embodiments of the disclosure.

FIG. 22 through FIG. 32 are schematic cross-sectional views of various stages in manufacturing a semiconductor structure in accordance with some alternative embodiments of the disclosure.

FIG. 33 through FIG. 42 are schematic cross-sectional views of various stages in manufacturing a semiconductor structure in accordance with some alternative embodiments of the disclosure.

FIG. 43 through FIG. 53 are schematic cross-sectional views of various stages in manufacturing a semiconductor structure in accordance with some alternative embodiments of the disclosure.

FIG. 54 through FIG. 57 are respectively schematic cross-sectional views of a semiconductor structure in accordance with alternative embodiments of the disclosure.

FIG. 58 is a schematic plane view of a substrate included a semiconductor structure in accordance with some embodiments of the disclosure.

FIG. 59 is a schematic plane view of a substrate included a semiconductor structure in accordance with some alternative embodiments of the disclosure.

FIG. 60 is a schematic cross-sectional view of an application of a semiconductor structure in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, “fifth”, “sixth”, “seventh”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the disclosure provides applicable concepts that can be embodied in a wide variety of specific contexts. The embodiments are intended to provide further explanations but are not used to limit the scope of the disclosure. The specific embodiment(s) described herein is related to a semiconductor structure (or a semiconductor device or package) having a glass core substrate of a multi-layer structure and a method of manufacturing the same, and is not intended to limit the scope of the disclosure. Due to the glass core substrate includes the multi-layer structure, an overall coefficient of thermal expansion (CTE) of the glass core substrate can be easily tuned by selecting materials of sub-layers included in the multi-layer structure of the glass core substrate, thereby greatly suppressing the warpage of the semiconductor structure. In addition, owing to the sub-layers included in the multi-layer structure of the glass core substrate, one or more passive semiconductor devices (such as integrated passives dies (IPDs) or so on, with or without same dimensions (e.g., in lateral direction and/or vertical direction)) can be easily integrated into the glass core substrate without cracks in the glass core substrate. The manufacture of such semiconductor structure in the disclosure is compatible to the current and/or advanced manufacturing processes.

In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

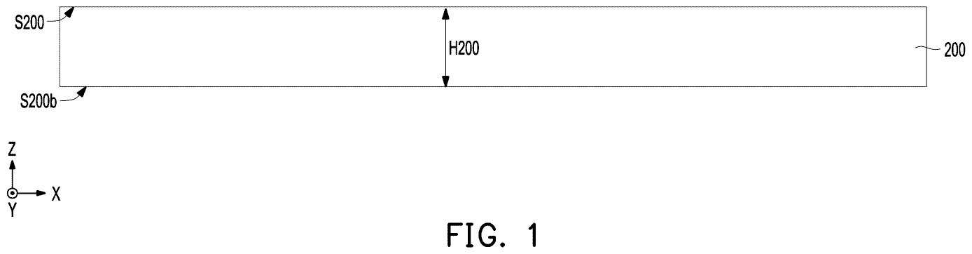

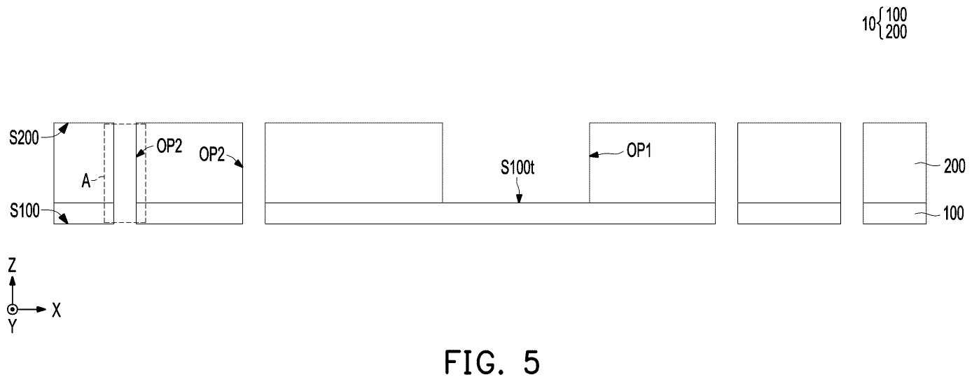

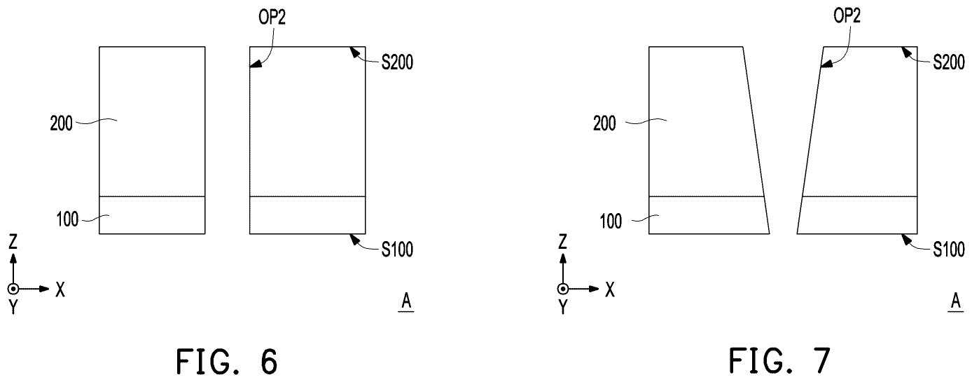

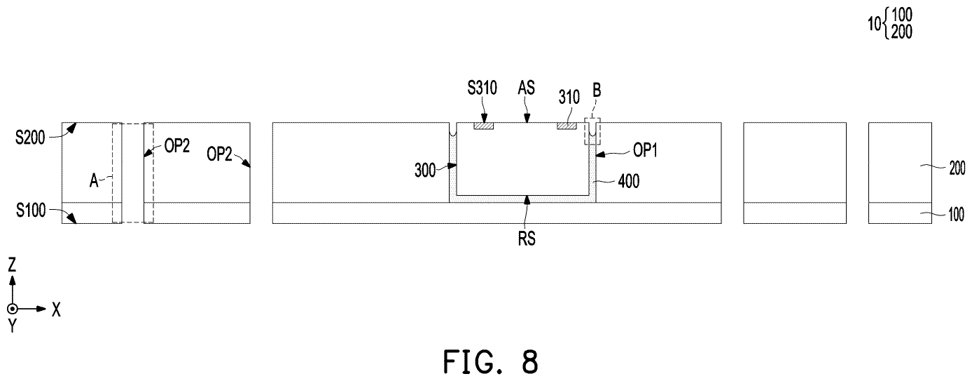

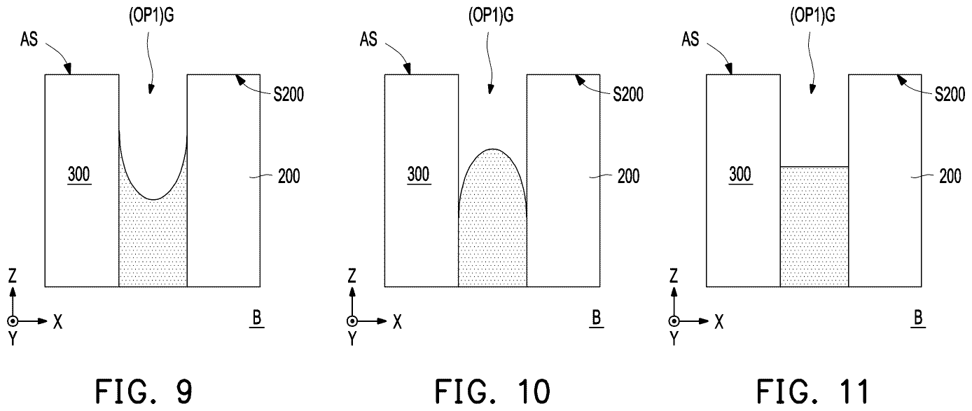

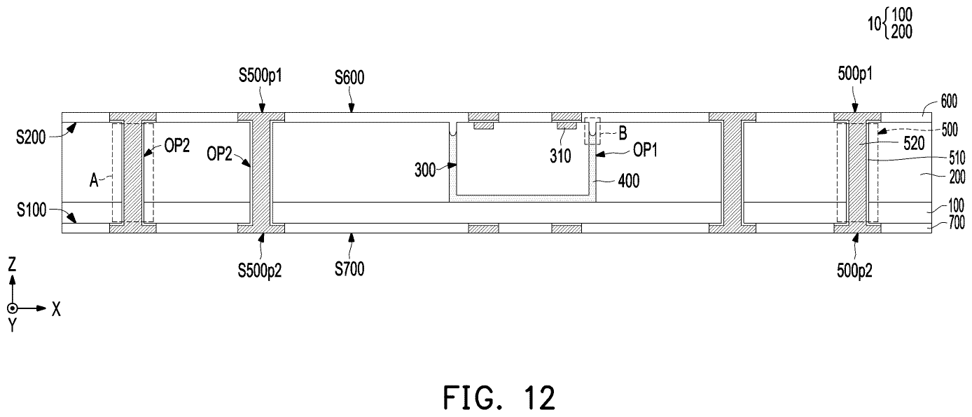

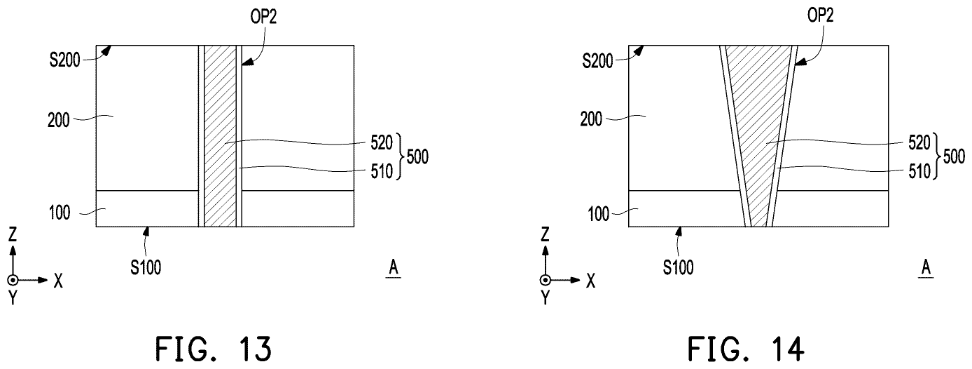

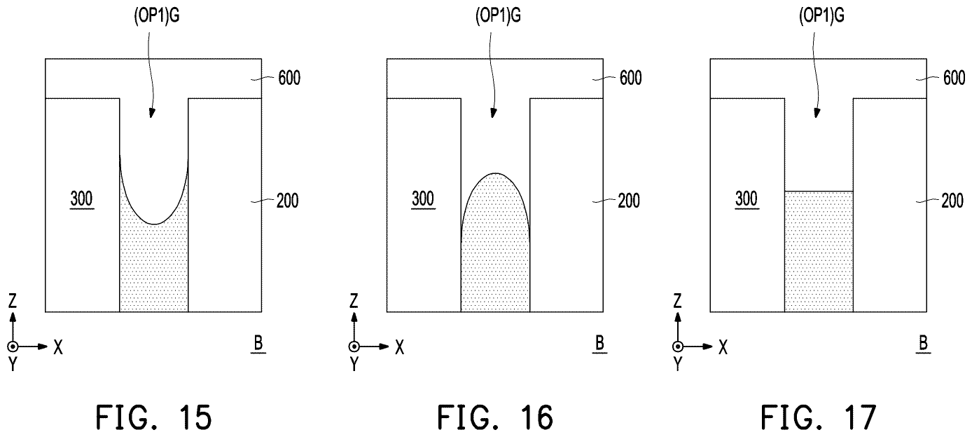

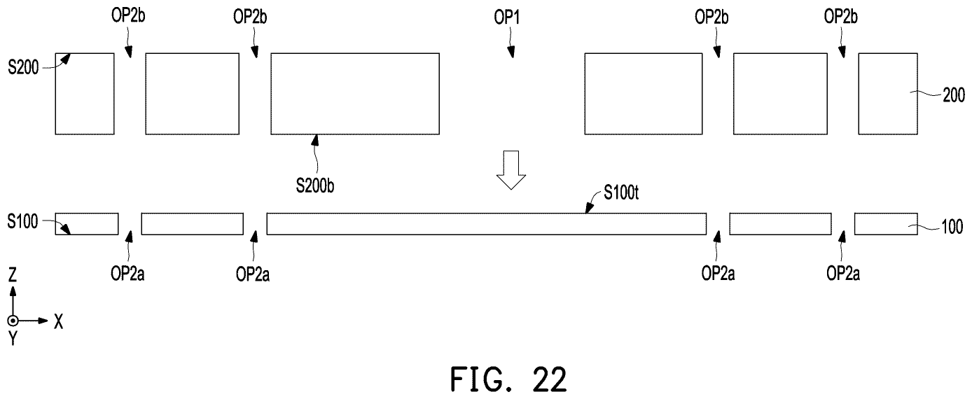

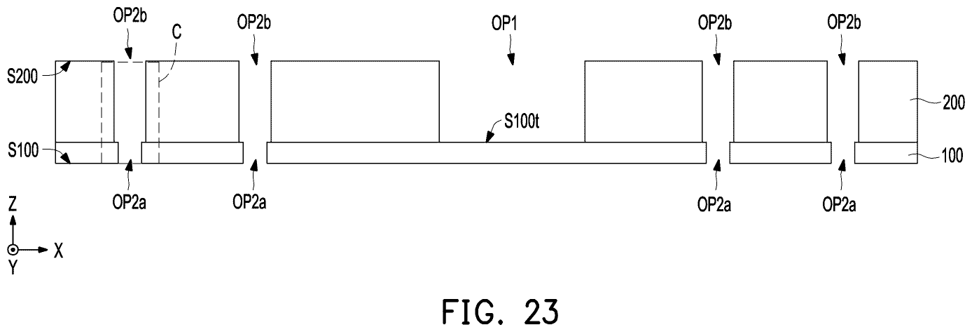

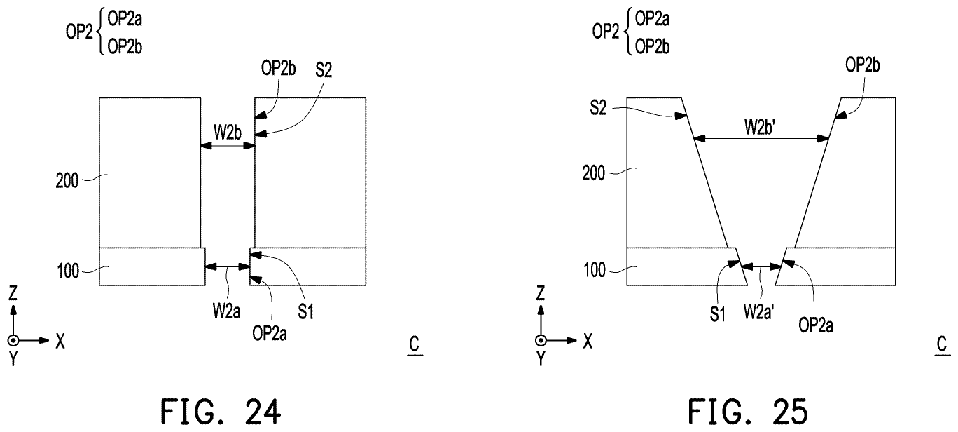

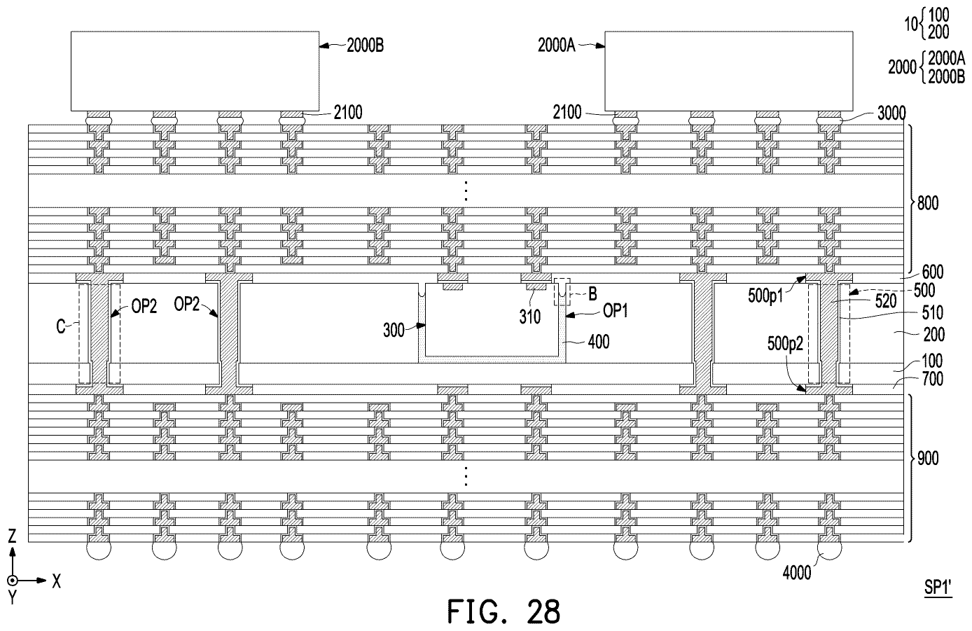

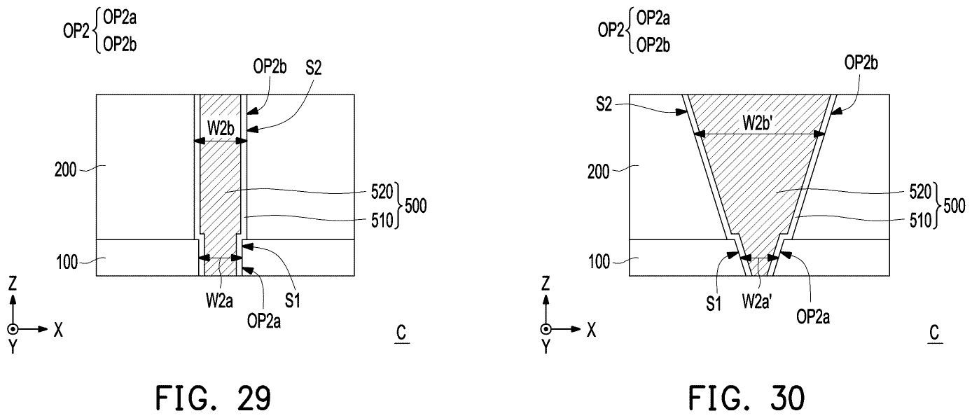

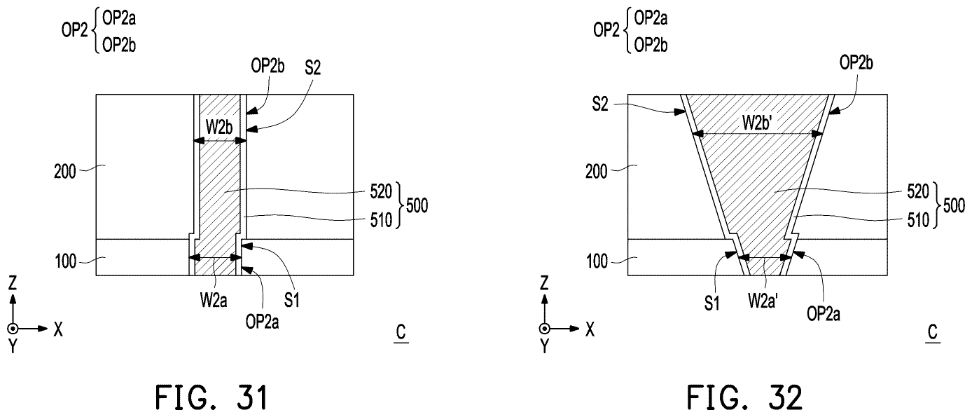

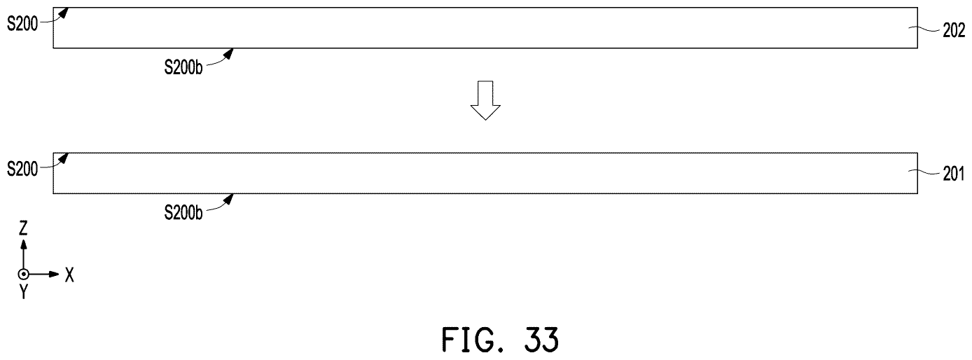

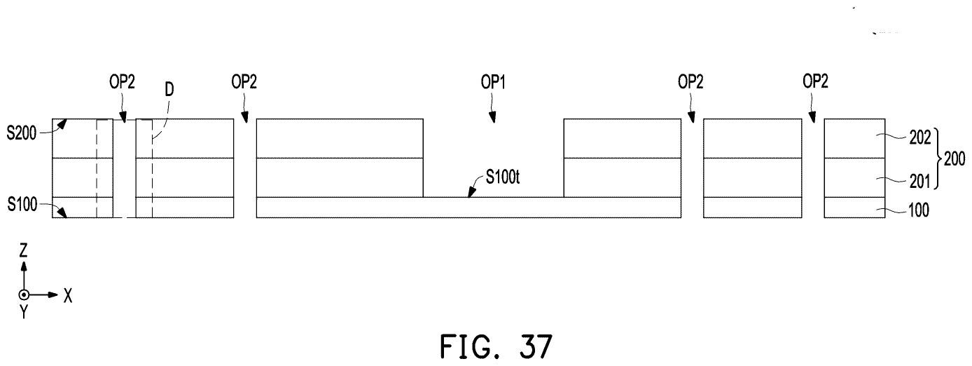

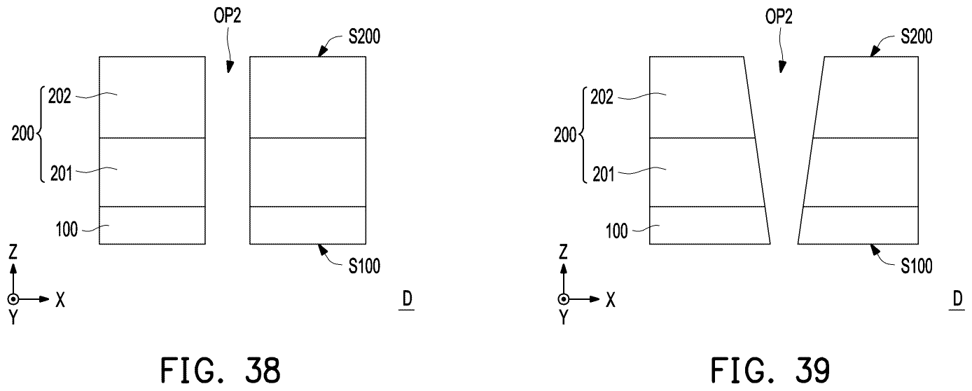

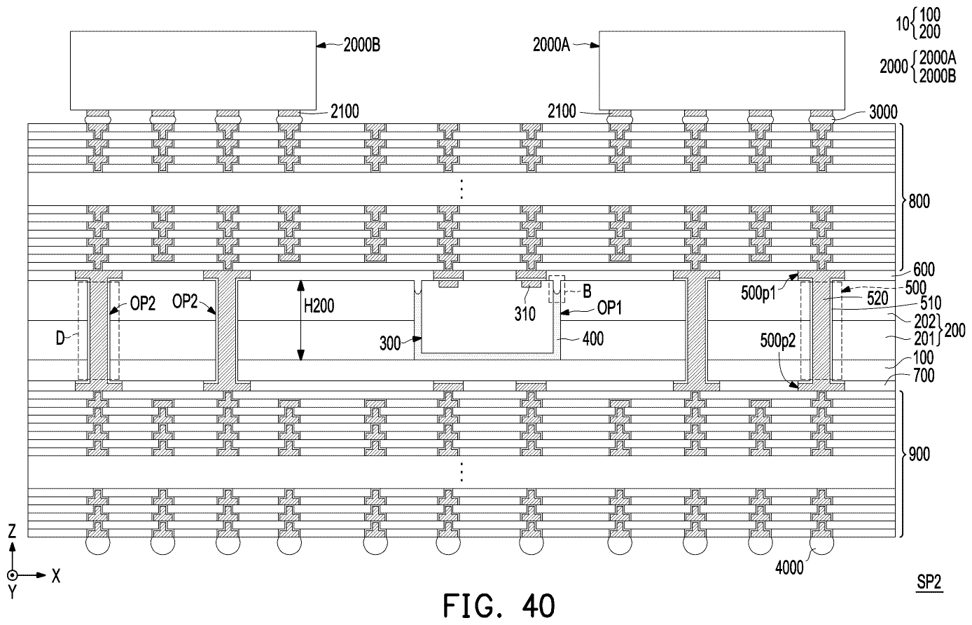

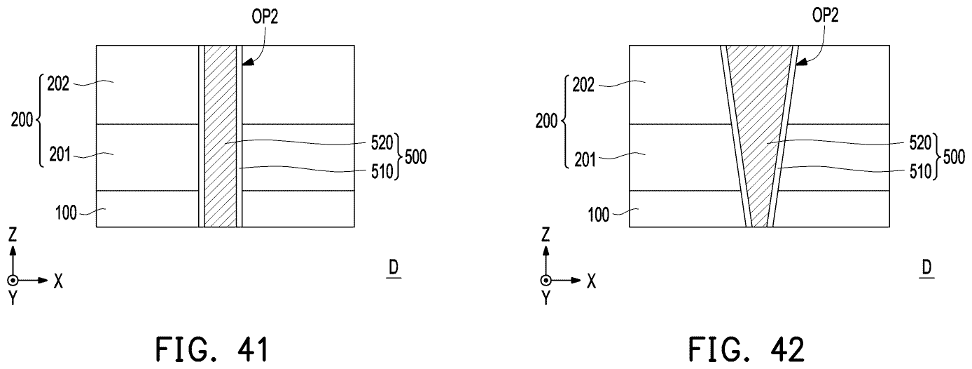

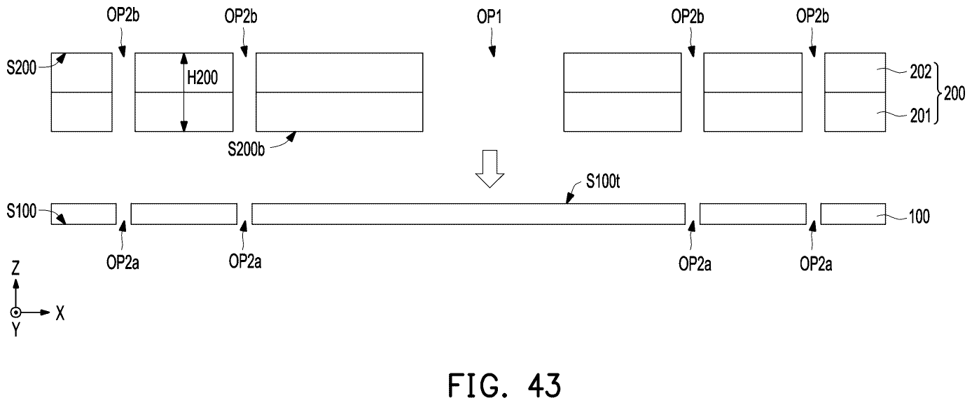

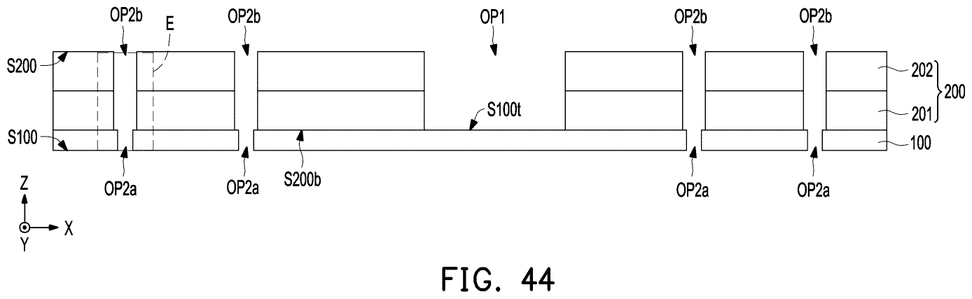

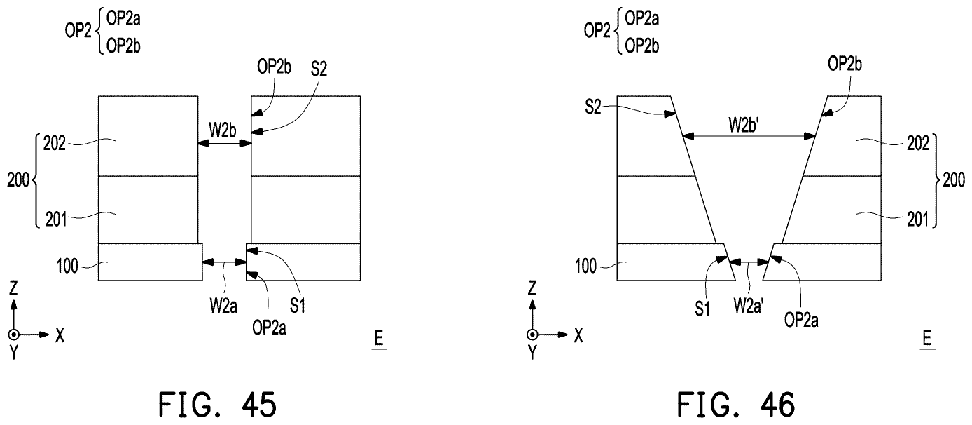

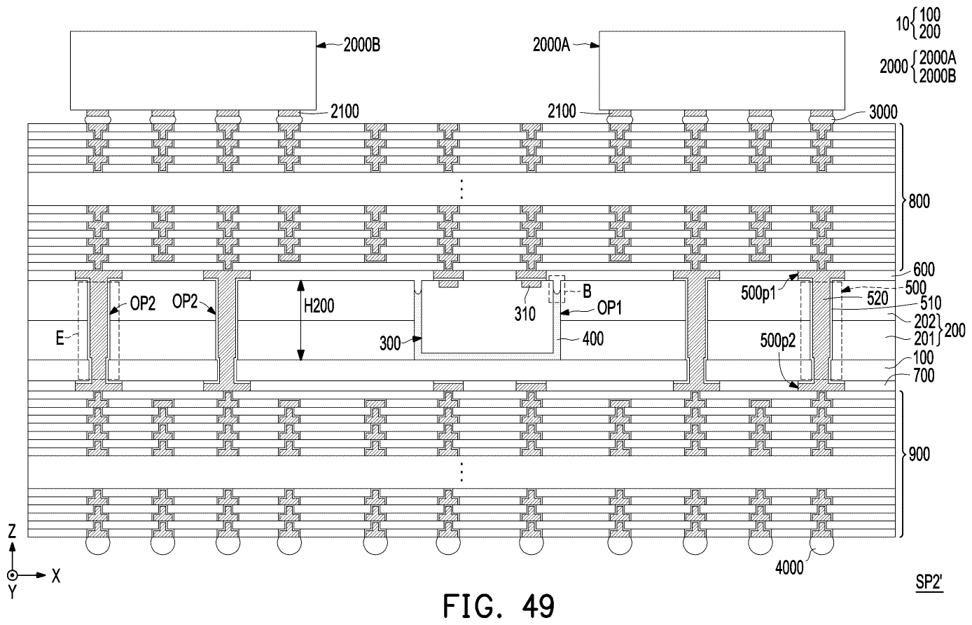

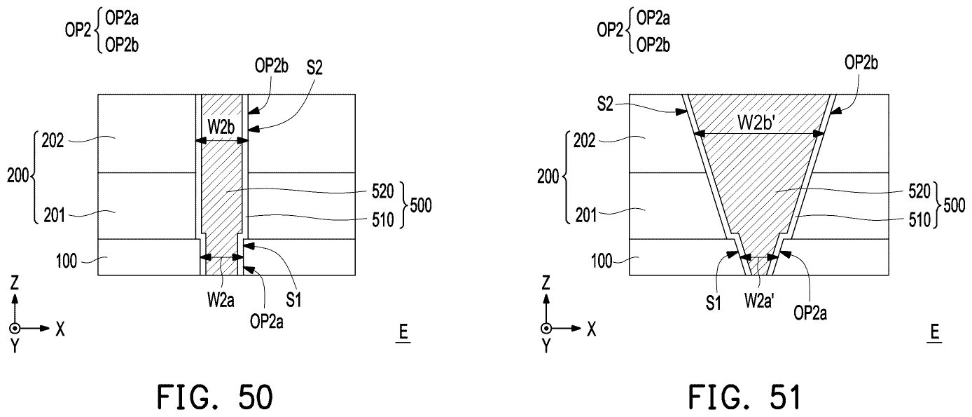

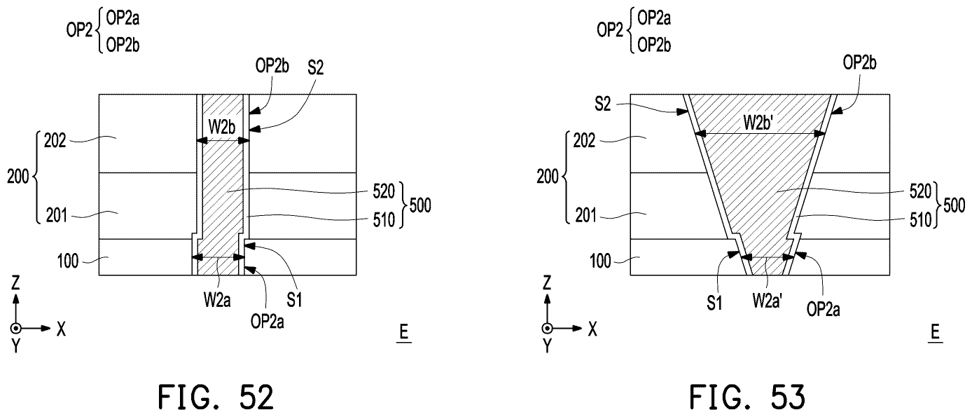

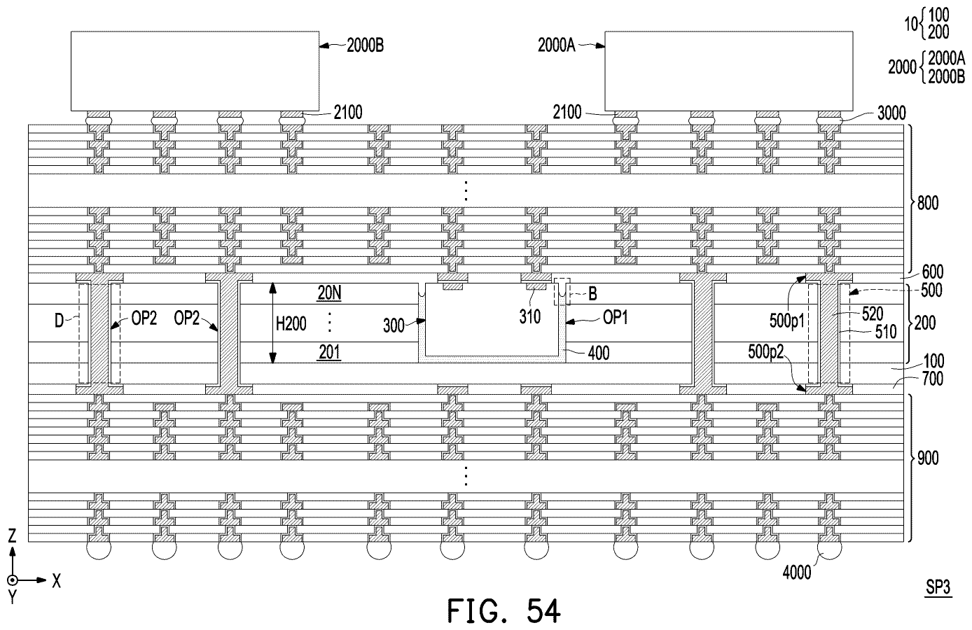

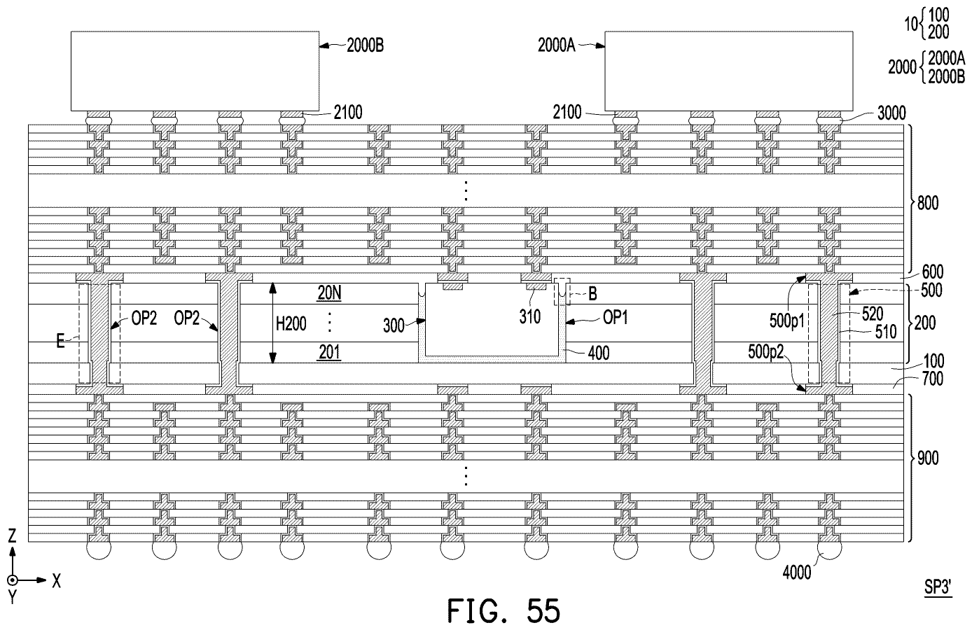

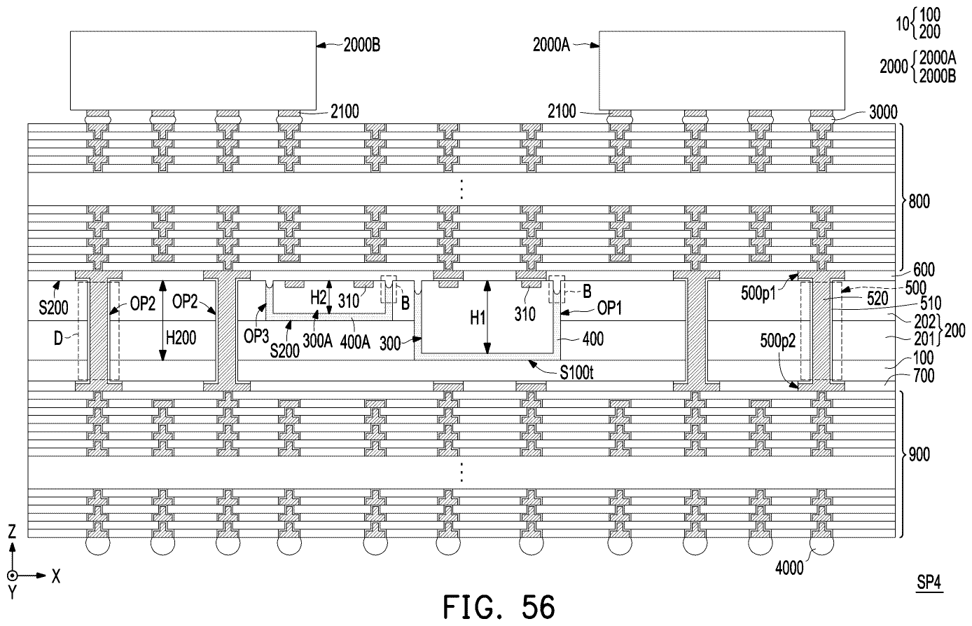

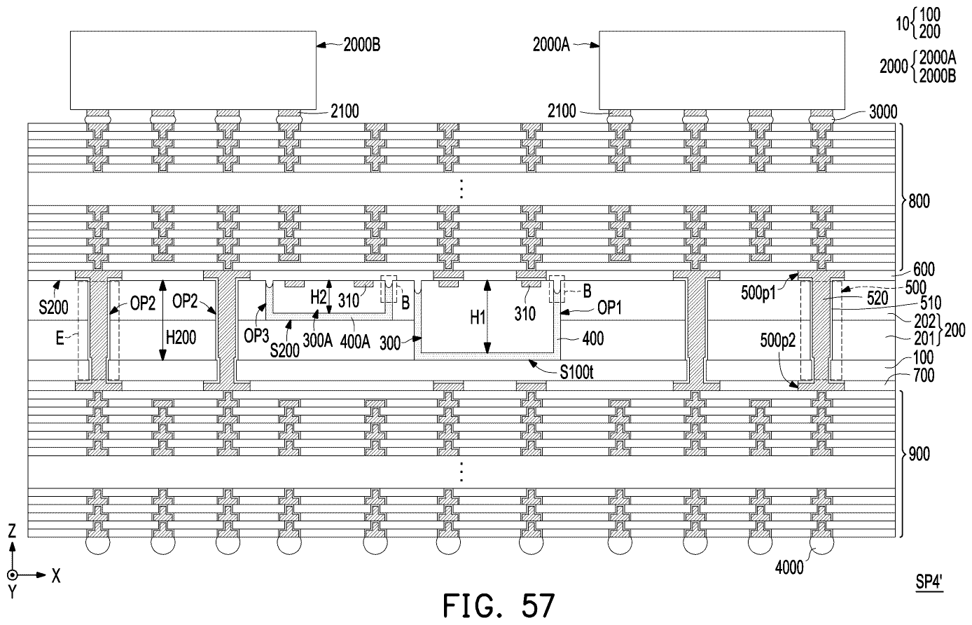

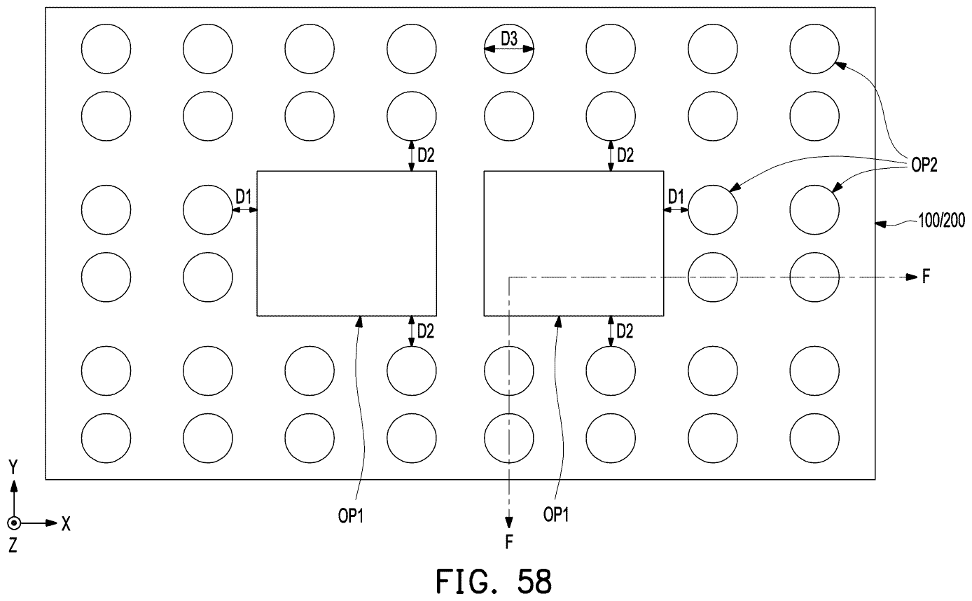

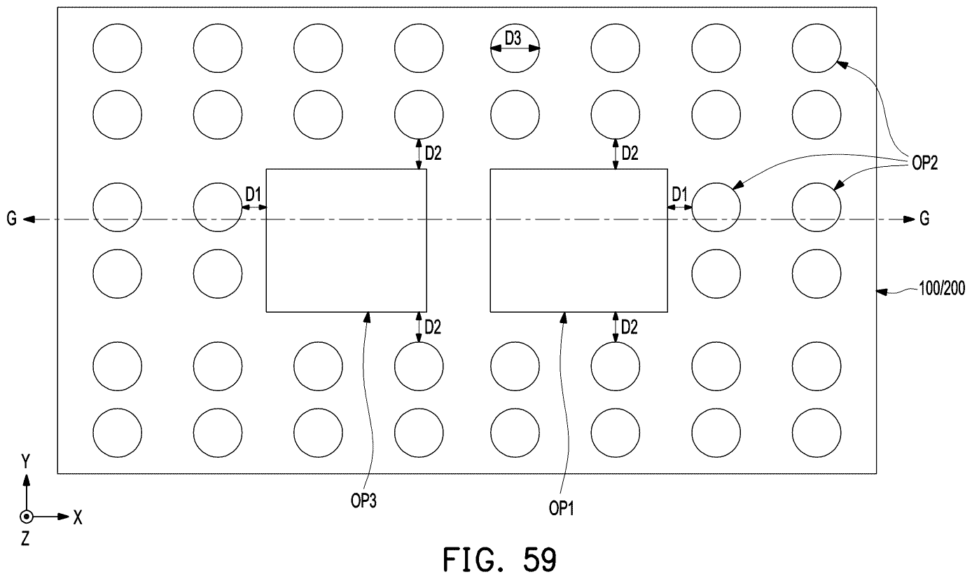

FIG. 1 through FIG. 21 are schematic cross-sectional views of various stages in manufacturing a semiconductor structure (e.g., SP1) in accordance with some embodiments of the disclosure, where the cross-sectional views of FIG. 1 through FIG. 21 are taken along a line FF depicted in the plane view of FIG. 58, the cross-sectional views of FIG. 6 and FIG. 7 are respectively showing various embodiments of enlarged views denoted in a dashed-box A depicted in FIG. 5, the cross-sectional views of FIG. 9 through FIG. 11 are respectively showing various embodiments of enlarged views denoted in a dashed-box B depicted in FIG. 8, the cross-sectional views of FIG. 13 and FIG. 14 are respectively showing various embodiments of enlarged views denoted in the dashed-box A depicted in FIG. 12, and the cross-sectional views of FIG. 15 through FIG. 17 are respectively showing various embodiments of enlarged views denoted in the dashed-box B depicted in FIG. 12. FIG. 22 through FIG. 32 are schematic cross-sectional views of various stages in manufacturing a semiconductor structure (e.g., SP1′) in accordance with some alternative embodiments of the disclosure, where the cross-sectional views of FIG. 22 through FIG. 32 are taken along the line FF depicted in the plane view of FIG. 58, the cross-sectional views of FIG. 24 through FIG. 27 are respectively showing various embodiments of enlarged views denoted in a dashed-box C depicted in FIG. 23, and the cross-sectional views of FIG. 29 through FIG. 32 are respectively showing various embodiments of enlarged views denoted in the dashed-box C depicted in FIG. 28. FIG. 33 through FIG. 42 are schematic cross-sectional views of various stages in manufacturing a semiconductor structure (e.g., SP2) in accordance with some alternative embodiments of the disclosure, where the cross-sectional views of FIG. 33 through FIG. 42 are taken along the line FF depicted in the plane view of FIG. 58, the cross-sectional views of FIG. 38 and FIG. 39 are respectively showing various embodiments of enlarged views denoted in a dashed-box D depicted in FIG. 37, and the cross-sectional views of FIG. 41 and FIG. 42 are respectively showing various embodiments of enlarged views denoted in the dashed-box D depicted in FIG. 40. FIG. 43 through FIG. 53 are schematic cross-sectional views of various stages in manufacturing a semiconductor structure (e.g., SP2′) in accordance with some alternative embodiments of the disclosure, where the cross-sectional views of FIG. 43 through FIG. 53 are taken along the line FF depicted in the plane view of FIG. 58, the cross-sectional views of FIG. 45 through FIG. 48 are respectively showing various embodiments of enlarged views denoted in a dashed-box E depicted in FIG. 44, and the cross-sectional views of FIG. 50 through FIG. 53 are respectively showing various embodiments of enlarged views denoted in the dashed-box E depicted in FIG. 49. FIG. 54 through FIG. 57 are respectively schematic cross-sectional views of a semiconductor structure (e.g., SP3, SP3′, SP4, or SP4′) in accordance with alternative embodiments of the disclosure, where the cross-sectional views of FIG. 54 and FIG. 55 are taken along the line FF depicted in the plane view of FIG. 58 and the cross-sectional views of FIG. 56 and FIG. 57 are taken along a line GG depicted in the plane view of FIG. 59. FIGS. 58 and 59 are schematic plane views of various embodiments of a substrate (e.g., 10) included a semiconductor structure in accordance with some embodiments of the disclosure.

Referring to FIG. 1, in some embodiments, a substrate 200 is provided. The substrate 200 has a surface S200 and a surface S200b opposite to the surface S200 along a direction Z, as shown in FIG. 1. For example, the substate 200 includes a glass substrate. A material of the substate 200 may include borosilicate glass, aluminosilicate glass, silica glass, or soda-lime glass. The disclosure is not limited thereto, alternatively, the material of the substrate 200 may be any suitable glass-based material. In some embodiments, a thickness H200 of the substrate 200 is approximately ranging from 10 μm to 1000 μm; although other suitable thickness may be adopted. In some embodiments, if considering a top or plane view (e.g., a X-Y plane) along the direction Z, the substate 200 is in a wafer or panel form. The substate 200 may be in a form of wafer-size having a diameter of about 4 inches or more. The substate 200 may be in a form of wafer-size having a diameter of about 6 inches or more. The substate 200 may be in a form of wafer-size having a diameter of about 8 inches or more. Or alternatively, the substate 200 may be in a form of wafer-size having a diameter of about 12 inches or more. The thickness H200 may be referred to as an overall thickness of the substrate 200. As shown in FIG. 58, the substrate 200 may be a panel form.

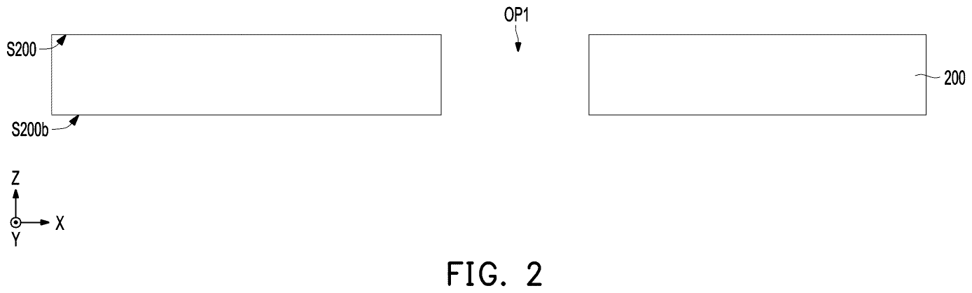

Referring to FIG. 2, in some embodiments, a patterning process is performed on the substrate 200 to form at least one through opening hole OP1 for accommodating a later-formed component (e.g., 300 in FIG. 8). Although only one through opening hole OP1 is shown in FIG. 2 through FIG. 5., FIG. 7, FIG. 9 and FIG. 18 through FIG. 21 and only two through opening holes OP1 are shown in FIG. 58, a number of the through opening hole OP1 is not limited in the disclosure. The number of the through opening hole OP1 can be selected and/or designated based on the demand and design requirements. For example, the through opening hole OP1 penetrates through the substrate 200, as shown in FIG. 2. In other words, the through opening hole OP1 extends from the surface S200 of the substrate 200 to the surface S200b of the substrate. The patterning process may include an etching process, a laser drilling process or other suitable patterning method, the disclosure is not limited thereto. In some embodiments, in the cross-section of FIG. 2, the through opening hole OP1 has substantially vertical sidewalls. However, the disclosure is not limited thereto; alternatively, in the cross-section, the through opening hole OP1 may have slant sidewalls. If considering the view top of FIG. 58, the shape of the through opening holes OP1 is rectangular; however, the disclosure is not limited thereto. Alternatively, in the view top, the shape of the through opening holes OP1 may be elliptical, oval, circular, square, tetragonal, octagonal or any suitable polygonal shape. In some embodiments, a distance (not label) between two adjacent the through opening holes OP1 is greater than or substantially equal to the distance D1 or D2.

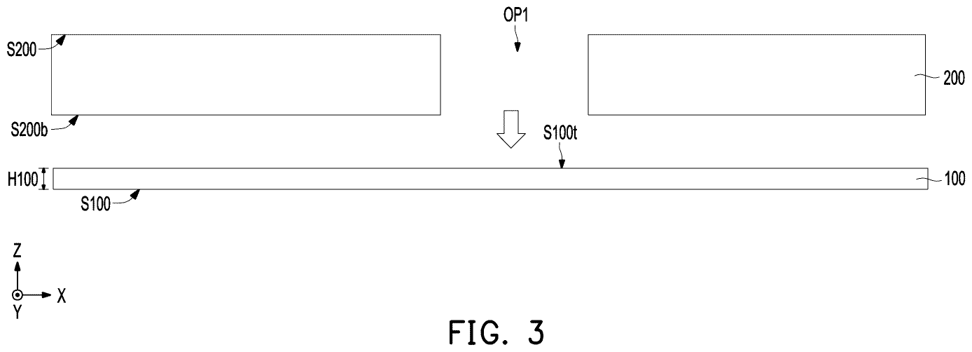

Referring to FIG. 3, in some embodiments, a substrate 100 is provided, and the substrate 200 with the through opening hole OP1 is then placed over the substrate 100. The substrate 100 has a surface S100t and a surface S100 opposite to the surface S100t along the direction Z, as shown in FIG. 3. For example, the substate 100 includes a glass substrate. A material of the substate 100 may include borosilicate glass, aluminosilicate glass, silica glass, or soda-lime glass. The disclosure is not limited thereto, alternatively, the material of the substrate 100 may be any suitable glass-based material. In some embodiments, the material of the substate 100 is different from the material of the substate 200. However, the disclosure is not limited thereto; alternatively, the material of the substate 100 may be the same as the material of the substate 200.

In some embodiments, a thickness H100 of the substrate 100 is approximately ranging from 30 μm to 1300 μm; although other suitable thickness may be adopted. In some embodiments, the thickness H100 of the substrate 100 is less than the thickness H200 of the substate 200. However, the disclosure is not limited thereto; alternatively, the thickness H100 of the substrate 100 may be greater than the thickness H200 of the substate 200. Or, the thickness H100 of the substrate 100 may be substantially equal to the thickness H200 of the substate 200. The thickness H100 may be referred to as an overall thickness of the substrate 100. In some embodiments, if considering a top or plane view (e.g., the X-Y plane) along the direction Z, the substate 100 is in a wafer or panel form. The substate 100 may be in a form of wafer-size having a diameter of about 4 inches or more. The substate 100 may be in a form of wafer-size having a diameter of about 6 inches or more. The substate 100 may be in a form of wafer-size having a diameter of about 8 inches or more. Or alternatively, the substate 100 may be in a form of wafer-size having a diameter of about 12 inches or more. As shown in FIG. 58, the substrate 100 may be a panel form. In some embodiments, in the top or plane view (e.g., the X-Y plane), the size and shape of the substrate 100 correspond to (e.g., the same as) the size and shape of the substrate 200 so to facilitate the sequence process(es).

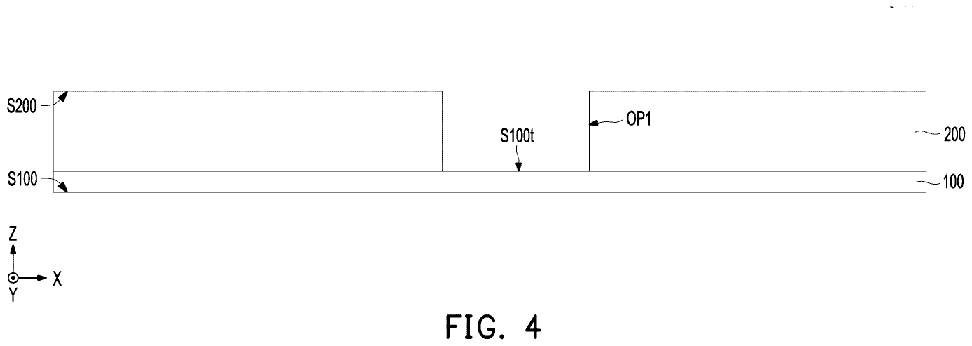

Referring to FIG. 3 and FIG. 4, in some embodiments, the substrate 200 is bonded to the substrate 100, where a portion of the surface S100t of the substrate 100 is accessibly revealed by the through opening hole OP1 formed in the substrate 200. The substrate 200 may be bonded to the substrate 100 through an adhesive or a fusion bonding. However, the disclosure is not limited thereto; alternatively, any suitable bonding process may be adopted as long as the bonding strength between the substrate 100 and the substrate 200 is sufficient to avoid delamination or electric short during the manufacture and operation of the semiconductor structure. After bonding the substrate 200 and the substrate 100, a substrate 10, which has a stacked structure, is formed, for example. In some embodiments, a surface roughness of the surface S100t exposed by the through opening hole OP1 is less than the surface roughness of the sidewalls of the through opening hole OP1. Due to the configuration of the substrate 10 (including the substrate 100 and the substrate 200), an overall CTE of the glass core substrate can be easily tuned by selecting materials of sub-layers (e.g., the substrate 100 and the substrate 200) included in the multi-layer structure of the substrate 10, thereby greatly suppressing the warpage of the semiconductor structure SP1. In some embodiments, the substrate 100 is referred to as a base substrate of the substrate 10, and the substrate 200 is referred to as a stacking substrate of the substrate 10.

Referring to FIG. 5, in some embodiments, after bonding the substrate 200 and the substrate 100 to form the substrate 10 having the stacked structure, a patterning process is performed on the substrate 10 to form a plurality of openings OP2 penetrating through the substrate 200 and the substrate 100. In such case, the openings OP2 extend form the surface S200 of the substrate 200 to the surface S100 of the substrate 100. In some embodiments, the openings OP2 are laterally next to (e.g., completely offset set from) the through opening holes OP1, as shown in the plane view of FIG. 58. For example, in the top or plane view (e.g., the X-Y plane), a lateral distance D1 or D2 between one through opening hole OP1 and a respective one opening OP2 immediately next thereto is greater than or substantially equal to 30 μm. The lateral distance D1 or D2 may be referred to as a minimum distance between the through opening hole OP1 and the openings OP2. Due to the lateral distances D1 and D2, it helps to reduce the buildup stress and prevent from internal cracks after RDL/buildup layers (e.g., 800 and 900) are completed. The number of the openings OP2 can be selected and designed based on the demand and design requirements.

In some embodiments, if considering the view top of FIG. 58, the shape of the openings OP2 is circular; however, the disclosure is not limited thereto. Alternatively, in the view top, the shape of the openings OP2 may be elliptical, oval, rectangular, square, tetragonal, octagonal or any suitable polygonal shape. The shapes of all of the openings OP2 are substantially identical to each other. However, the disclosure is not limited thereto; alternatively, in the view top, the shapes of a first group of the openings OP2 may be different from the shapes of a second group of the openings OP2. In some embodiments, if considering the view top of FIG. 58, the sizes of all of the openings OP2 is substantially identical to each other. However, the disclosure is not limited thereto; alternatively, in the view top, the sizes of a first group of the openings OP2 may be different from the sizes of a second group of the openings OP2. For example, the sizes of the first group of the openings OP2 are greater than the sizes of the second group of the openings OP2, where the first group of the openings OP2 may be used for power and/or ground, and the second group of the openings OP2 may be used for signals and/or ground. In some embodiments, a lateral size D3 of the openings OP2 is approximately ranging from 10 μm to 250 μm.

As shown in FIG. 5 and FIG. 6, in some embodiments, the sidewalls of the opening OP2 are vertical sidewalls that continuously extend from the surface S200 of the substrate 200 to the surface S100 of the substrate 100. In some alternative embodiments, the sidewalls of the opening OP2 are slant sidewalls that continuously extend from the surface S200 of the substrate 200 to the surface S100 of the substrate 100, see FIG. 7. The disclosure is not limited thereto.

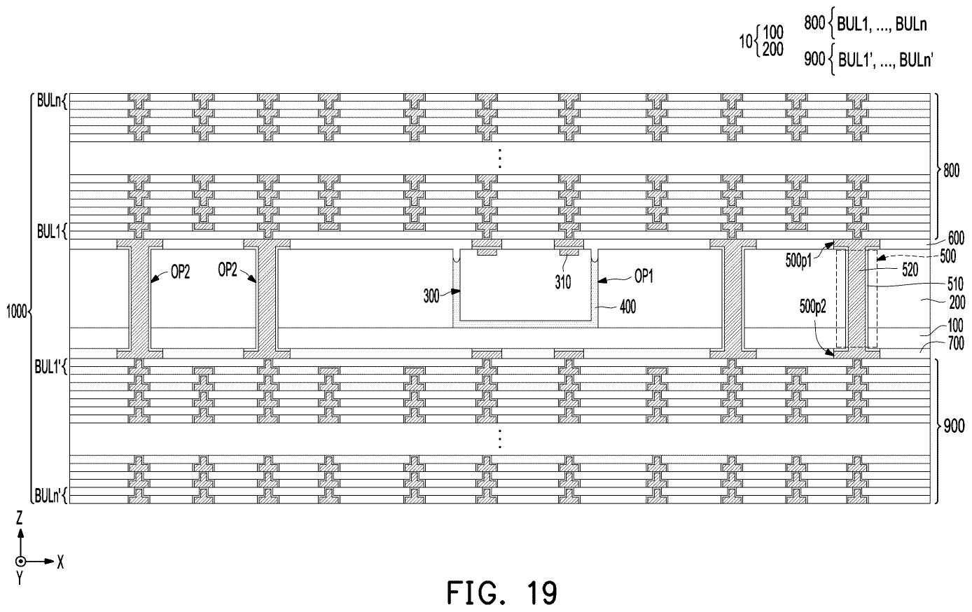

Referring to FIG. 8, in some embodiments, a semiconductor device 300 is provided and placed into the through opening hole OP1. Only one semiconductor device 300 is shown in FIG. 8 for illustrative purposes, the number of the semiconductor device 300 corresponds to the number of the through opening hole OP1. In other words, the semiconductor device 300 and the through opening hole OP1 are in one-to-one configuration. In some embodiments, the semiconductor device(s) 300 may, independently, include an integrated passives die (IPD). In addition, the semiconductor device(s) 300 may further, independently, include one or more functions of an electrical and/or optical input/output (I/O) interface die, a IPD, a voltage regulator (VR) die, a local silicon interconnect (LSI) die with or without deep trench capacitor (DTC) features, a local silicon interconnect (LSI) die with multi-tier functions such as electrical and/or optical network circuit interfaces, IPD, VR, DTC, or the like. The types of the semiconductor device(s) 300 may be selected and designated based on the demand and design requirements, and thus are not specifically limited in the disclosure. For example, the semiconductor device(s) 300 includes IPDs. As shown in FIG. 8, for example, the semiconductor device 300 includes a plurality of conductive pads 310 distributed on an active side AS of the semiconductor device 300 for electrical connections to later-formed components (e.g., 500p1 in FIGS. 12 and/or 800 in FIG. 19).

In some embodiments, the semiconductor device 300 is integrated into (e.g., installed into) the substrate 10 by an adhesive 400. The adhesive 400 may include a liquid-type adhesive (such as a glue or the like) or a film-type adhesive (such as a die attach film or the like), the disclosure is not limited thereto. As shown in FIG. 8 and FIG. 9, the semiconductor device 300 may be adhered to the substrate 10 (e.g., the surface S100t of the substrate 100 exposed by the through opening hole OP1 and at least a part of the sidewall of the through opening hole OP1) through the adhesive 400. For example, the adhesive 400 extends on a rear side RS of the semiconductor device 300 and further extends onto the sidewalls of the semiconductor device 300, where the adhesive 400 at least does not fill up a space (e.g., G in FIG. 9) of the through opening hole OP1 disposed between the semiconductor device 300 and the substrate 200. In other words, the space G is in the through opening hole OP1 disposed between the semiconductor device 300 and the substrate 200, after integrating the semiconductor device 300 into the substrate 10 by the adhesive 400. In such case, the rear side RS of the semiconductor device 300 is completely covered by the adhesive 400, and the sidewalls of the semiconductor device 300 and the sidewall of the through opening hole OP1 are partially covered by the adhesive 400. The adhesive 400 may have a convex top surface in relative to the surface S200 of the substrate 200, see FIG. 8 and FIG. 9. However, the disclosure is not limited thereto; alternatively, the adhesive 400 may have a concave top surface in relative to the surface S200 of the substrate 200, see FIG. 10. Or, the adhesive 400 may have a substantially planar top surface in relative to the surface S200 of the substrate 200, see FIG. 11. In some embodiments, the illustrated top surface of the adhesive 400 is lower than the surface S200 of the substrate 200 and the active side AS of the semiconductor device 300. Owing to such configuration, the active surface AS and the surface S200 of the substrate 200 would not be contaminated by the adhesive 400.

In some embodiments, the active surface AS of the semiconductor device 300 is substantially level with the surface S200 of the substrate 200, as shown in FIG. 8. In other words, the active surface AS of the semiconductor device 300 is substantially coplanar to the surface S200 of the substrate 200. In such case, the thickness of the semiconductor device 300 is less than the thickness H200 of the substrate 200. However, the disclosure is not limited thereto, alternatively, the active surface AS of the semiconductor device 300 is lower than the surface S200 of the substrate 200. Or, the active surface AS of the semiconductor device 300 is above the surface S200 of the substrate 200. In such case, the thickness of the semiconductor device 300 is greater than or substantially equal to the thickness H200 of the substrate 200.

In some embodiments, during the placement of the semiconductor device 300, the openings OP2 may be covered by temporary photomask or sacrificial layer to avoid possible contamination to the openings OP2. After the placement of the semiconductor device 300, the temporary photomask or sacrificial layer may be removed. Due to the configuration of the substrate 10 (including the through opening holes only in the substrate 200), one or more semiconductor devices 300 can be easily integrated into the substrate 10 without cracks in the substrate 10.

In some embodiments, in the top or plane view of FIG. 58, the lateral sizes of the semiconductor devices 300 may be different from each other. However, the disclosure is not limited thereto; alternatively, the lateral sizes of all of the semiconductor devices 300 may be the same. Or, the lateral sizes of a first group of the semiconductor devices 300 may be the same, and the lateral sizes of a second group of the semiconductor devices 300 may be the same, and the lateral sizes of the second group are different from the lateral sizes of the first group. In some embodiment, the semiconductor devices 300 have substantially identical thickness in the direction Z.

Referring to FIG. 12, in some embodiments, a seed layer 510 is formed on sidewalls of the openings OP2 and a part of the surface S200 and the surface S100, and a conductive portion 520 is formed on the seed layer 510 to form a plurality of conductive pillars 500 inside the substrate 10, a plurality of contact pads 500p1 on the surface S200 and a plurality of contact pads 500p2 on the surface S100. In some embodiments, at least some of the contact pads 500p1 are physically and electrically connected to the conductive pillars 500, and at least some of the contact pads 500p1 are physically and electrically connected to one end of each of the conductive pads 310 of the semiconductor device 300 for further electrical connections. On the other hand, at least some of the contact pads 500p2 are physically and electrically connected to other end of each the conductive pillars 500 for further electrical connections, in some embodiments. For example, some of the contact pads 500p1 are electrically coupled to some of the contact pads 500p2 through the conductive pillars 500. As shown in FIG. 12, the contact pads 500p1 are laterally covered by a dielectric layer 600 disposed on the surface S200 of the substrate 10, and the contact pads 500p2 are laterally covered by a dielectric layer 700 disposed on the surface S100 of the substrate 10. As shown in FIG. 12, the semiconductor device 300 may be electrically connected to some of the contact pads 500p1. In addition, the contact pads 500p1 may be further electrically coupled to some of the contact pads 500p2 by some of the contact pads 500p1 and some of conductive pillars 500. The disclosure is not limited thereto.

In some embodiments, the formation of the conductive pillars 500, the contact pads 500p1 and the contact pads 500p2 may include, but not limited by, forming a first photoresist mask (not shown) on the surface S200 of the substrate 10 and the semiconductor device 300 and a second photoresist mask (not shown) on the surface S100 of the substrate 10, where the first and second photoresist masks independently have a plurality of holes (not shown) corresponding to the openings OP2 and the predetermined locations of forming the contact pads 500p1 or 500p2; globally forming a seed layer material (not shown) over the first and second photoresist masks and the substrate 10 (e.g., on the surfaces S200 and S100) and the semiconductor device 300 exposed by the first and second photoresist masks, and the seed layer material further extends onto the conductive pads 310 of the semiconductor device 300 and the sidewalls of the openings OP2; forming a conductive material (not shown) on the seed layer material, where the conductive material fills up the openings OP2; and removing the first and second photoresist masks by lifting process so to pattern the seed layer material to form the seed layer 510 and pattern the conductive material to form the conductive portion 520 over the substrate 10, thereby forming the contact pads 500p1 on the surface S200 of the substrate 10, the contact pads 500p2 on the surface S100 of the substrate 10 and the conductive pillars 500 in the openings OP2 formed in the substrate 10. As shown in FIG. 12, each of the contact pads 500p1, 500p2 and the conductive pillars 500 is constituted by the seed layer 510 and the conductive portion 520. In addition, a dielectric liner (not shown) (e.g., silicon nitride, an oxide, a polymer, a combination thereof, etc.) may be further optionally formed between the seed layer 510 and the substrate 10. In such embodiments, each of the contact pads 500p1, 500p2 and the conductive pillars 500 is constituted by the optional dielectric liner, the seed layer 510 and the conductive portion 520.

In some embodiments, the seed layer 510 are referred to as a metal layer, which may be a single layer or a composite layer comprising a plurality of sub-layers formed of different materials. In some embodiments, the seed layer 510 include titanium, copper, molybdenum, tungsten, titanium nitride, titanium tungsten, combinations thereof, or the like. For example, the seed layer 510 may include a titanium layer and a copper layer over the titanium layer. The seed layer 510 may be formed using, for example, sputtering, physical vapor deposition (PVD). or the like. In some embodiment, the conductive material is formed by plating process (such as electroplating or electroless plating), deposition or sputtering. The conductive material may be copper, copper alloy, aluminum, aluminum alloy, or combinations thereof. For example, the conductive portion 520 includes patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc. The material of the first and second photoresist masks may include a positive photo-resist or a negative photo-resist; the disclosure is not limited thereto.

After forming the conductive pillars 500, the contact pads 500p1 and the contact pads 500p2, the dielectric layer 600 is formed on the surface S200 of the substrate to laterally cover the contact pads 500p1 and also cover the substrate 10 and the semiconductor device 300 exposed by the contact pads 500p1, and the dielectric layer 700 is formed on the surface S100 of the substrate to laterally cover the contact pads 500p2 and also cover the substrate 10 exposed by the contact pads 500p2. In some embodiments, the formation of dielectric layer 600 and dielectric layer 700 may include, but not limited to, respectively forming a blanket layer of dielectric material over the contact pads 500p1, 500p2 and the substrate 10 and the semiconductor device 300 exposed by the contact pads 500p1 and the contact pads 500p2; and patterning the dielectric material blanket layers to form the dielectric layer 600 accessibly revealing the contact pads 500p1 and covering the substrate 10 and the semiconductor device 300 exposed by the contact pads 500p1 and the dielectric layer 700 accessibly revealing the contact pads 500p2 and covering the substrate 10 exposed by the contact pads 500p2. As shown in FIG. 12, surfaces S500p1 of the contact pads 500p1 are substantially level with a surface S600 of the dielectric layer 600, for example. The surfaces S500p1 of the contact pads 500p1 may be substantially coplanar to the surface S600 of the dielectric layer 600. As shown in FIG. 12, surfaces S500p2 of the contact pads 500p2 are substantially level with a surface S700 of the dielectric layer 700, for example. The surfaces S500p2 of the contact pads 500p2 may be substantially coplanar to the surface S700 of the dielectric layer 700.

In some embodiments, the material of the dielectric material may be polyimide, PBO, BCB, a nitride such as silicon nitride, an oxide such as silicon oxide, phosphosilicate glass (PSG), borosilicate glass (BSG), boron-doped phosphosilicate glass (BPSG), a combination thereof or the like, which may be patterned using grinding process, a chemical mechanical polishing (CMP) process, an etching process, combination thereof, or the like. The etching process may include a dry etching, a wet etching, or a combination thereof. In some embodiments, the dielectric material may be formed by suitable fabrication techniques such as spin-on coating, chemical vapor deposition (CVD), (e.g. plasma-enhanced chemical vapor deposition (PECVD)), or the like. The disclosure is not limited thereto. Up to here, a glass core substrate is manufactured, where the glass core substrate includes the substrate 10, the conductive pillars 500 penetrating through the substrate 10, the contact pads 500p1 disposed on the substrate 10 (e.g., on the surface S200) and electrically coupled to the conductive pillars 500, the contact pads 500p2 disposed on the substrate 10 (e.g., on the surface S100) and electrically coupled to the conductive pillars 500, the dielectric layer 600 disposed on the substrate 10 (e.g., on the surface S200) and laterally covering the contact pads 500p1, and the dielectric layer 700 disposed on the substrate 10 (e.g., on the surface S100) and laterally covering the contact pads 500p2.

As shown in FIG. 12 and FIG. 13, the conductive pillar 500 has vertical sidewalls that continuously extend from the surface S200 of the substrate 200 to the surface S100 of the substrate 100, for example. However, the disclosure is not limited thereto, the conductive pillar 500 may have slant sidewalls that continuously extend from the surface S200 of the substrate 200 to the surface S100 of the substrate 100, see FIG. 14. Due to the seed layer 510 and the conductive portion 520 (continuously extending from the substrate 200 to the substrate 100 inside the openings OP2), the bonding strength between the substrate 200 and the substrate 100 can be enhanced and the stress at the interface of the substrate 200 and the substrate 100 inside the openings OP2 can be suppressed, thereby avoiding potential internal cracks of the substate 10 included in the glass core substrate. In some embodiments, the dielectric layer 600 further extends into the space G, see FIG. 15 through FIG. 17. That is to say, the space G is filled up by dielectric layer 600, where a part of the sidewalls of the semiconductor device 300 (exposed by the space G) is further covered by the dielectric layer 600.

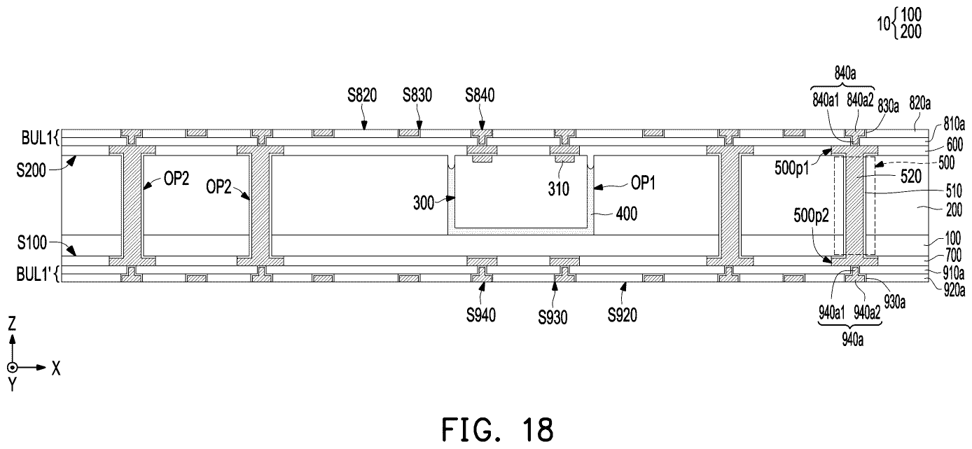

Referring to FIG. 18 and FIG. 19, in some embodiments, a redistribution circuit structure 800 and a redistribution circuit structure 900 are formed on two opposite sides of the substrate 10 to be electrically connected to the contact pads 500p1 and the contact pads 500p2, respectively. That is, the redistribution circuit structure 800 and the redistribution circuit structure 900 provide the routing functions to the components formed in the glass core substrate (e.g., the contact pads 500p1, 500p2, the conductive pillars 500 and the semiconductor device(s) 300). As shown in FIG. 18, a build-up layer BUL1 is formed on the contact pads 500p1 and the dielectric layer 600, and a build-up layer BUL1′ is formed on the contact pads 500p2 and the dielectric layer 700, where the build-up layer BUL1 is disposed on (e.g., in physical contact with) and electrically coupled to the contact pads 500p1 and the semiconductor device 300, and the build-up layer BUL1′ is disposed on (e.g., in physical contact with) and electrically coupled to the contact pads 500p2, where the build-up layer BUL1 is electrically coupled to the build-up layer BUL1′ through the contact pads 500p1, the conductive pillars 500 and the contact pads 500p2, for example.

The formation of the build-up layer BUL1 may include, but not limited to, forming a blanket layer of a first dielectric material (not shown) over the contact pads 500p1 and the dielectric layer 600; forming a blanket layer of a second dielectric material (not shown) over the first dielectric material blanket layer so to sandwich the first dielectric material blanket layer between the second dielectric material blanket layer and the contact pads 500p1 and between the second dielectric material blanket layer and the dielectric layer 600; patterning the first dielectric material blanket layer and the second dielectric material blanket layer to form a first dielectric layer 810a and a second dielectric layer 820a disposed thereon, where a plurality of first openings (not labeled) penetrate through the first dielectric layer 810a and the second dielectric layer 820a; forming a seed layer 830a in the first openings; and forming a conductive material in the first openings to form a conductive layer 840a over the seed layer 830a so to form a metallization layer in the first openings, thereby forming the build-up layer BUL1. For example, as shown in FIG. 18, the metallization layer of the build-up layer BUL1 includes the seed layer 830a and the conductive layer 840a standing thereon and electrically connected thereto, and is embedded in a dielectric structure of the build-up layer BUL1, where the dielectric structure includes the first dielectric layer 810a and the second dielectric layer 820a stacked thereon. As shown in FIG. 18, the conductive layer 840a is electrically connected to the contact pads 500p1 and the conductive pads 310 of the semiconductor device 300 through the seed layer 830a, in some embodiments.

In some embodiments, the first dielectric layer 810a and the second dielectric layer 820a have different materials. For example, the first dielectric layer 810a includes an Ajinomoto buildup (ABF) film, a silicon carbide (SiC) layer, a silicon nitride (Si3N4) layer, an aluminum oxide layer, or the like. For example, the second dielectric layer 820a includes a silicon-rich oxide (SRO) layer. In some embodiments, the second dielectric layer 820a is referred to as an inter-metal dielectric (IMD) layer which may be made of a dielectric material, such as silicon oxide, silicon nitride, silicon oxynitride, a spin-on dielectric material, an ABF film, or a low-k dielectric material. It should be noted that the low-k dielectric materials are generally dielectric materials having a dielectric constant lower than 3.9. In some alternative embodiments, the first dielectric layer 810a and the second dielectric layer 820a have different etching selectivities. In the case, the first dielectric layer 810a may be referred to as an etching stop layer to prevent the underlying elements (e.g., the contact pads 500p1 and the conductive pads 310) from damage caused by the over-etching.

In some embodiments, the first dielectric material blanket layer and the second dielectric material blanket layer are patterned through a set(s) of photolithography and etching processes. The etching process may include a dry etching, a wet etching, or a combination thereof. After the etching process, a cleaning step may be optionally performed, for example to clean and remove the residue generated from the etching process. However, the disclosure is not limited thereto, and the etching process may be performed through any other suitable method. The first openings each may include a trench hole (not labeled) in the second dielectric layer 820a and a via hole (not labeled) in the first dielectric layer 810a and spatially communicated to the trench hole. In some embodiments, the first openings include a dual damascene structure. The formation of the first openings is not limited to the disclosure. The formation of opening (with the dual damascene structure) can be formed by any suitable forming process, such as a via first approach or a trench first approach.

As shown in FIG. 18, a lateral size of the trench holes formed in the second dielectric layer 820a may be greater than a lateral size of the via holes formed in the first dielectric layer 810a. In some embodiments, a sidewall of each of the via holes is a vertical sidewall. In alternative embodiments, the sidewall of each of the via holes is a slant sidewall. In some embodiments, a sidewall of each of the trench holes is a vertical sidewall. In alternative embodiments, the sidewall of each of the trench holes is a slant sidewall. The sidewall of one via hole and the sidewall of a respective one trench hole may be collectively referred to as a sidewall of one opening. For illustrative purposes, the number of the first openings shown in FIG. 18 does not limit the disclosure, and may be designated and selected based on the demand and design requirements. As illustrated in FIG. 18, portions of the metallization layer formed in the trench holes may be referred to as conductive traces or conductive wires 840a2 horizontally extended (e.g., extending in the direction X and/or the direction Y), and portions of the metallization layer formed in the via holes may be referred to as conductive vias 840a1 vertically extended (e.g., extending in the direction Z).

In some embodiment, the seed layer 830a and the conductive layer 840a are sequentially formed in the first openings by, but not limited to, conformally forming a blanket layer made of metal or metal alloy materials over the dielectric structure and extending into the first openings, so to line the sidewalls of the first openings; filling the conductive material in the first openings; and removing excess amount of the blanket layer made of metal or metal alloy materials and the conductive material over the illustrated top surface (e.g., a surface S820) of the second dielectric layer 820a, thereby the metallization layer including the seed layer 830a and the conductive layer 840a is manufactured. The removal may be performed by a planarizing process such as a mechanical grinding, a CMP, and/or an etching process. After the planarizing process, a cleaning process may be optionally performed, for example to clean and remove the residue generated from the planarizing process. However, the disclosure is not limited thereto, and the planarizing process may be performed through any other suitable method.

In some embodiments, the seed layer 830a is referred to as a metal layer, which can be a single layer or a composite layer including a plurality of sub-layers formed of different materials. In some embodiments, the seed layer 830a includes titanium, copper, molybdenum, tungsten, titanium nitride, titanium tungsten, combinations thereof, or the like. For example, the seed layer 830a may include a titanium layer and a copper layer over the titanium layer. The seed layer 830a may be formed using, for example, sputtering, PVD, or the like.

In some embodiments, a material of the conductive material includes a suitable conductive material, such as metal and/or metal alloy. For example, the conductive material can be Al, aluminum alloys, Cu, copper alloys, or combinations thereof (e.g., AlCu), the like, or combinations thereof. In some embodiments, the conductive material is formed by plating process or any other suitable method, which the plating process may include electroplating or electroless plating, or the like. In alternative embodiments, the conductive material may be formed by deposition. The disclosure is not limited thereto. In the case, an illustrated top surface (including a surface S830 of the seed layer 830a and a surface S840 of the conductive layer 840a) of the metallization layer is substantially level with an illustrated top surface (e.g., the surface S820 of the second dielectric layer 820a) of the dielectric structure. That is, the illustrated top surface (including the surface S830 of the seed layer 830a and the surface S840 of the conductive layer 840a) of the metallization layer is substantially coplanar to the illustrated top surface (e.g., the surface S820 of the second dielectric layer 820a) of the dielectric structure. In some embodiments, a dielectric liner (not shown) (e.g., silicon nitride, an oxide, a polymer, a combination thereof, etc.) may be further optionally formed between the seed layer 830a and the dielectric structure (including the first dielectric layer 810a and the second dielectric layer 820a). Due to the dielectric liner, the diffusion of metal atoms (e.g., Cu) of the metallization layer to the adjacent layers (e.g., 810a, 820a, 600) can be suppressed.

The formation of the build-up layer BUL1′ may include, but not limited to, forming a blanket layer of a first dielectric material (not shown) over the contact pads 500p2; forming a blanket layer of a second dielectric material (not shown) over the first dielectric material blanket layer so to sandwich the first dielectric material blanket layer between the second dielectric material blanket layer and the contact pads 500p2; patterning the first dielectric material blanket layer and the second dielectric material blanket layer to form a first dielectric layer 910a and a second dielectric layer 920a disposed thereon, where a plurality of second openings (not labeled) penetrate through the first dielectric layer 910a and the second dielectric layer 920a; forming a seed layer 930a in the second openings; and forming a conductive material in the second openings to form a conductive layer 940a over the seed layer 930a so to form a metallization layer in the second openings, thereby forming the build-up layer BUL1′. For example, as shown in FIG. 18, the metallization layer of the build-up layer BUL1′ includes the seed layer 930a and the conductive layer 940a standing thereon and electrically connected thereto, and is embedded in a dielectric structure of the build-up layer BUL1′, where the dielectric structure includes the first dielectric layer 910a and the second dielectric layer 920a stacked thereon. As shown in FIG. 18, the conductive layer 940a is electrically connected to the contact pads 500p2 through the seed layer 930a, in some embodiments.

The details, formations and materials of the first dielectric layer 910a, the second dielectric layer 920a, the seed layer 930a and the conductive layer 940a is similar to or substantially identical to the details, formations and materials of the first dielectric layer 810a, the second dielectric layer 820a, the seed layer 830a and the conductive layer 940a previously discussed, and thus are not repeated herein. In the case, the first dielectric layer 910a may be referred to as an etching stop layer to prevent the underlying elements (e.g., the contact pads 500p2) from damage caused by the over-etching.

The second openings each may include a trench hole (not labeled) in the second dielectric layer 920a and a via hole (not labeled) in the first dielectric layer 910a and spatially communicated to the trench hole. As shown in FIG. 18, a lateral size of the trench holes formed in the second dielectric layer 920a may be greater than a lateral size of the via holes formed in the first dielectric layer 910a. In some embodiments, a sidewall of each of the via holes is a vertical sidewall. In alternative embodiments, the sidewall of each of the via holes is a slant sidewall. In some embodiments, a sidewall of each of the trench holes is a vertical sidewall. In alternative embodiments, the sidewall of each of the trench holes is a slant sidewall. The sidewall of one via hole and the sidewall of a respective one trench hole may be collectively referred to as a sidewall of one opening. For illustrative purposes, the number of the second openings shown in FIG. 18 does not limit the disclosure, and may be designated and selected based on the demand and design requirements. As illustrated in FIG. 18, portions of the metallization layer formed in the trench holes may be referred to as conductive traces or conductive wires 940a2 horizontally extended (e.g., extending in the direction X and/or the direction Y), and portions of the metallization layer formed in the via holes may be referred to as conductive vias 940a1 vertically extended (e.g., extending in the direction Z).

In some embodiments, an illustrated bottom surface (including a surface S930 of the seed layer 930a and a surface S940 of the conductive layer 940a) of the metallization layer is substantially level with an illustrated bottom surface (e.g., a surface S920 of the second dielectric layer 920a) of the dielectric structure. That is, the illustrated bottom surface (including the surface S930 of the seed layer 930a and the surface S940 of the conductive layer 940a) of the metallization layer is substantially coplanar to the illustrated bottom surface (e.g., the surface S920 of the second dielectric layer 920a) of the dielectric structure. In some embodiments, a dielectric liner (not shown) (e.g., silicon nitride, an oxide, a polymer, a combination thereof, etc.) may be further optionally formed between the seed layer 930a and the dielectric structure (including the first dielectric layer 910a and the second dielectric layer 920a). Due to the dielectric liner, the diffusion of metal atoms (e.g., Cu) of the metallization layer to the adjacent layers (e.g., 910a, 920a, 700) can be suppressed.

Continued on FIG. 18 and FIG. 19, in some embodiments, the rest of build-up layers (e.g., up to BULn) included in the redistribution circuit structure 800 and the rest of build-up layers (e.g., up to BULn′) included in the redistribution circuit structure 900 are respectively formed on the build-up layer BUL1 of the redistribution circuit structure 800 and the build-up layer BUL1′ of the redistribution circuit structure 900, thereby forming the redistribution circuit structure 800 and the redistribution circuit structure 900. The details, formations and materials of the build-up layers included in the redistribution circuit structure 800 are similar to or substantially identical to the build-up layer BUL1 of the redistribution circuit structure 800 previously discussed in FIG. 18, and the details, formations and materials of the build-up layers included in the redistribution circuit structure 900 are similar to or substantially identical to the build-up layer BUL1′ of the redistribution circuit structure 900 previously discussed in FIG. 18, and thus are not repeated herein. In some embodiments, the number of the build-up layers (e.g., up to BULn) included in the redistribution circuit structure 800 are equal to the number of the build-up layers (e.g., up to BULn′) included in the redistribution circuit structure 900 (such as n=n′), as shown in FIG. 19. However, the disclosure is not limited thereto; alternatively, the number of the build-up layers (e.g., up to BULn) included in the redistribution circuit structure 800 may be less than the number of the build-up layers (e.g., up to BULn′) included in the redistribution circuit structure 900 (such as n<n′). Or, the number of the build-up layers (e.g., up to BULn) included in the redistribution circuit structure 800 may be greater than the number of the build-up layers (e.g., up to BULn′) included in the redistribution circuit structure 900 (such as n>n′). The total number of the build-up layers included in the redistribution circuit structure 800 and the total number of the build-up layers included in the redistribution circuit structure, independently, may be one, two, three, four, five, six, seven, eight, nine, ten, eleven, twelve, or more, the disclosure is not limited thereto. Up to here, an integrated substrate 1000 is manufactured.

However, the disclosure is not limited thereto; alternatively, the redistribution circuit structures 800, 900 may be formed by lamination process.

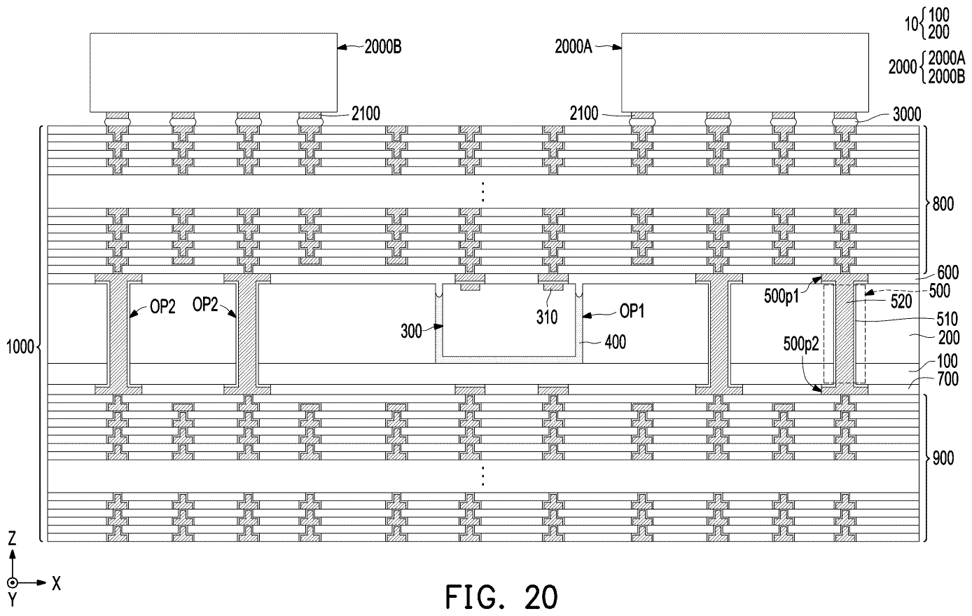

Referring to FIG. 20, in some embodiments, a semiconductor die (or device or package) is provided and bonded to the redistribution circuit structure 800 of the integrated substrate 1000. For illustrative purposes, only two semiconductor dies 2000 (e.g., including 2000A and 2000B) are shown in FIG. 20, but the number of the semiconductor dies 2000 may be one, two, three, or more, the disclosure is not limited thereto. The number of the semiconductor dies 2000 can be selected and designed based on the demand and design requirements. As shown in FIG. 20, the semiconductor dies 2000, independently, may include a plurality of conductive pads 2100 distributed on an active side thereof, where the semiconductor dies 2000 may be bonded to the integrated substrate 1000 through a plurality of connectors 3000 disposed therebetween. The semiconductor dies 2000 are mounted to the integrated substrate 1000 through the connectors 3000 by flip chip bonding. For example, the connectors 3000 include solder regions. The connectors 3000 independently may include lead or be lead-free, and may include Sn-Ag, Sn-Cu, Sn-Ag-Cu, or the like. For example, the connectors 3000 include micro-bumps or the like. The connectors 3000 independently may be referred to as solder regions, conductive connectors, conductive elements. For example, the semiconductor dies 2000 are physically and electrically connected to the integrated substrate 1000 through the connectors 3000.

It is appreciated that, in some embodiments, the semiconductor dies 2000 independently described herein may be referred to as a semiconductor chip or package or an integrated circuit (IC). In some embodiments, the semiconductor dies 2000 independently is a logic chip (e.g., a central processing unit (CPU), a graphics processing unit (GPU), a neural network processing unit (NPU), a deep learning processing unit (DPU), a tensor processing unit (TPU), a system-on-a-chip (SoC), an application processor (AP), a system-on-integrated-circuit (SoIC), and a microcontroller); a power management die (e.g., a power management integrated circuit (PMIC) die); a wireless and radio frequency (RF) die; a baseband (BB) die; a sensor die (e.g., a photo/image sensor chip); a micro-electro-mechanical-system (MEMS) die; a signal processing die (e.g., a digital signal processing (DSP) die); a front-end die (e.g., an analog front-end (AFE) die); an application-specific die (e.g., an application-specific integrated circuit (ASIC)); a field-programmable gate array (FPGA); a combination thereof; any suitable logic circuits; or the like. The semiconductor dies 2000 independently may be or include a digital chip, an analog chip or a mixed signal chip. The semiconductor dies 2000 independently may be a chip or an IC of combination-type, such as a WiFi chip simultaneously including both of a RF chip and a digital chip.

In alternative embodiments, the semiconductor dies 2000 independently includes a memory die (e.g., a dynamic random-access memory (DRAM) die, static random-access memory (SRAM) die, a synchronous dynamic random-access memory (SDRAM), a resistive random-access memory (RRAM) die, a magnetoresistive random-access memory (MRAM) die, a NAND flash a wide I/O memory (WIO) die, a high bandwidth memory (HBM) die, the like, etc.). That is to say, the semiconductor dies 2000 independently includes a hybrid memory cube (HMC) module, a HBM module, or the like; in some embodiments.

In alternative embodiments, the semiconductor dies 2000 independently is an artificial intelligence (AI) engine such as an AI accelerator; a computing system such as an AI server, a high-performance computing (HPC) system, a high-power computing device, a cloud computing system, a networking system, an edge computing system, an immersive memory computing system (ImMC), a SoIC system, etc. ; a combination thereof; or the like.

In some embodiments, the types of all of the semiconductor dies 2000 are identical. In alternative embodiments, the types of some of the semiconductor dies 2000 are different from each other, while the types of some of the semiconductor dies 2000 are identical types. In further alternative embodiments, the types of all of the semiconductor dies 2000 are different. In some embodiments, the sizes of all of the semiconductor dies 2000 are the same. In alterative embodiments, the sizes of some of the semiconductor dies 2000 are different from each other, while the sizes of some of the semiconductor dies 2000 are the same sizes. In further alternative embodiments, the sizes of all of the semiconductor dies 2000 are different. In some embodiments, the shapes of all of the semiconductor dies 2000 are identical. In alternative embodiments, the shapes of some of the semiconductor dies 2000 are different from each other, while the shapes of some of the semiconductor dies 2000 are identical. In further alternative embodiments, the shapes of all of the semiconductor dies 2000 are different. The types, sizes and shapes of each of the semiconductor dies 2000 are independent from each other, and may be selected and designed based on the demand and design layout, the disclosure is not limited thereto. For example, the semiconductor dies 2000 are electrically coupled and electrically communicated to each other through the integrated substrate 1000, and the semiconductor dies 2000 are electrically coupled and electrically communicated to the semiconductor device(s) 300 through the connectors 3000, the redistributor circuit structure 800 and the contact pads 500p1. In some embodiments, the semiconductor dies 2000 are electrically coupled to the conductive pillars 500 through the connectors 3000, the redistributor circuit structure 800 and the contact pads 500p1. In some embodiments, the semiconductor dies 2000 are electrically coupled to the redistribution circuit structure 900 through the connectors 3000, the redistributor circuit structure 800, the contact pads 500p1 and the conductive pillars 500.

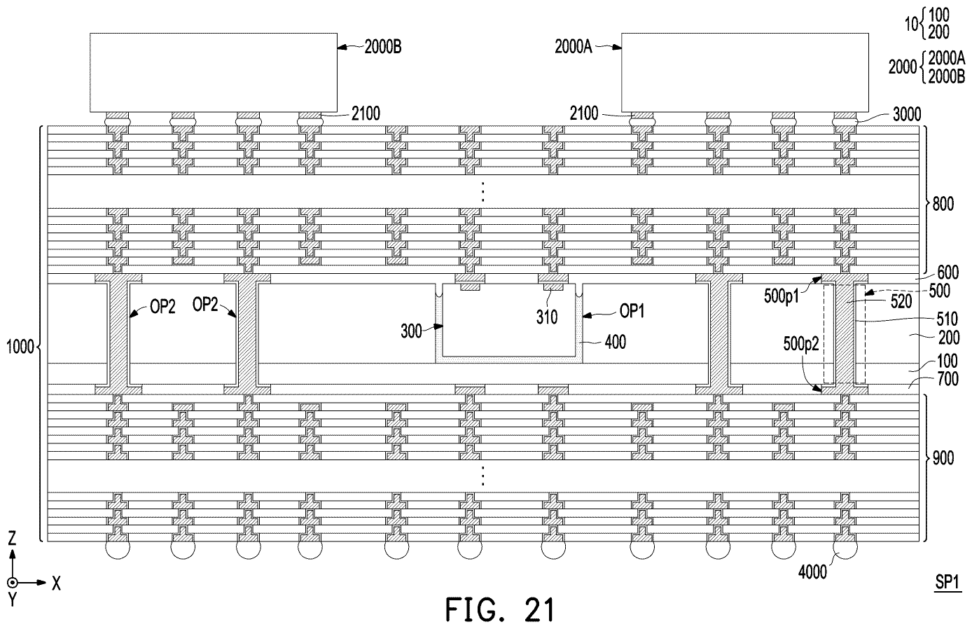

Referring to FIG. 21, in some embodiments, a plurality of conductive terminals 4000 are formed on the redistribution circuit structure 900 of the integrated substrate 1000, where the conductive terminals 4000 are electrically connected to the integrated substrate 1000. The conductive terminals 4000 includes a ball grid array (BGA) bumps (for example, which may have, but not limited to, a size of about 400 μm), electroless nickel-immersion gold technique (ENIG) formed bumps, electroless nickel-electroless palladium-immersion gold technique (ENEPIG) formed bumps, or the like, in some embodiments. The conductive terminals 4000 may be referred to as connectors, conductive connectors, conductive elements of the integrated substrate 1000 for external connections (e.g., to a motherboard or the like). For example, the semiconductor dies 2000 are electrically coupled to the conductive terminals 4000 through the connectors 3000, the redistributor circuit structure 800, the contact pads 500p1, the conductive pillars 500, the contact pads 500p2 and the redistributor circuit structure 900. The semiconductor device(s) 300 may be electrically coupled to some of the conductive terminals 4000 through the redistributor circuit structure 800, the contact pads 500p1, the conductive pillars 500, the contact pads 500p2 and the redistributor circuit structure 900. Or, the semiconductor device(s) 300 may be electrically coupled to some of the conductive terminals 4000 through the contact pads 500p1, the conductive pillars 500, the contact pads 500p2 and the redistributor circuit structure 900. Up to here, the semiconductor structure SP1 is manufactured.

In the above embodiments, the openings OP2 are formed in the substrate 200 and substrate 100 of the substrate 10 in a single patterning process (see the process of FIG. 5), however, the disclosure is not limited thereto. In alternatively embodiments, the substrate 100 is patterned to form a plurality of openings OP2a in a first patterning process (see FIG. 22), the substrate 200 is patterned form a plurality of openings OP2b in a second patterning process (see FIG. 22), and then the substrate 200 is bonded to the substrate 100 (see FIG. 23). The first and second patterning processes may be similar to or substantially identical to the patterning process previously described in FIG. 5, and the bonding process may be similar to or substantially identical to the bonding process previously described in FIG. 3 and FIG. 4; and thus, are not repeated herein. As shown in FIG. 23, in the cross-section, the openings OP2a formed in the substrate 100 are at least partially overlapped with the openings OP2b formed in the substrate 200, where the openings OP2a formed in the substrate 100 and the openings OP2b formed in the substrate 200 are spatially communicated to each other so to form a plurality of openings OP2.

In some embodiments, the through opening holes OP1 and the openings OP2 are formed in same process. Alternatively, the through opening holes OP1 and the openings OP2 may be formed in different processes. Due to the configuration of the substrate 10 (including the through opening holes only in the substrate 200), one or more semiconductor devices 300 can be easily integrated into the substrate 10 without cracks in the substrate 10.

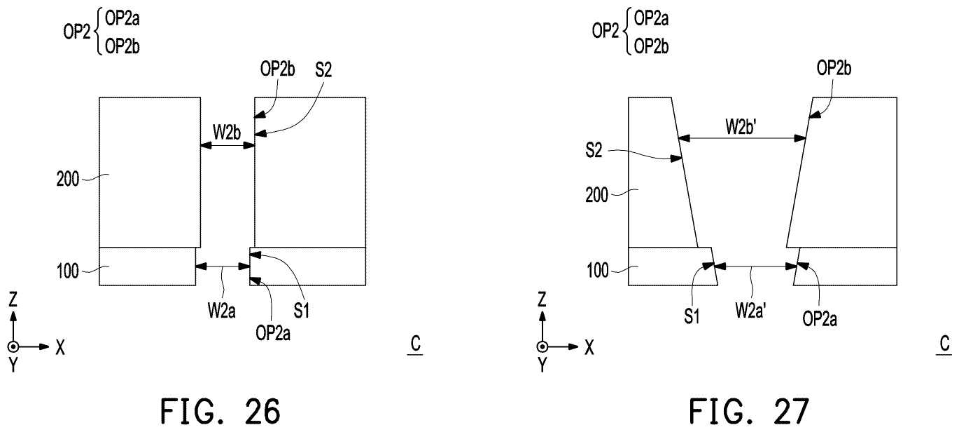

Referring to FIG. 23 and FIG. 24, sidewalls (e.g., S1) the opening OP2a include vertical sidewalls, and sidewalls (e.g., S2) the opening OP2b include vertical sidewalls. In some alternative embodiments, the sidewalls (e.g., S1) the opening OP2a include slant sidewalls, and the sidewalls (e.g., S2) the opening OP2b include slant sidewalls, see FIG. 25. The disclosure is not limited thereto. As shown in FIG. 24 and FIG. 25, a lateral size W2a of one opening OP2a is less than a lateral size W2b of a respective one opening OP2b, where an offset is between the sidewall S2 of the OP2b and the sidewall S1 of the OP2a. Or, the lateral size W2a of one opening OP2a is greater than the lateral size W2b of a respective one opening OP2b, where an offset is between the sidewall S2 of the OP2b and the sidewall S1 of the OP2a. In some embodiments, the lateral size W2a of one opening OP2a is substantially equal to the lateral size W2b of a respective one opening OP2b, where an offset is between the sidewall S2 of the OP2b and the sidewall S1 of the OP2a due to misalignment, see FIG. 26. The disclosure is not limited thereto. Alternatively, the lateral size W2a of one opening OP2a may be substantially equal to the lateral size W2b of a respective one opening OP2b, where there is no offset between the sidewall S2 of the OP2b and the sidewall S1 of the OP2a, similar to the configuration shown in FIG. 6. In some embodiments, the maximum lateral size W2a of one opening OP2a is substantially equal to the minimum lateral size W2b of a respective one opening OP2b, where an offset is between the sidewall S2 of the OP2b and the sidewall S1 of the OP2a due to misalignment, see FIG. 27. The disclosure is not limited thereto. Alternatively, the maximum lateral size W2a of one opening OP2a may be substantially equal to the minimum lateral size W2b of a respective one opening OP2b, where there is no offset between the sidewall S2 of the OP2b and the sidewall S1 of the OP2a, similar to FIG. 7.

Referring to FIG. 28, in some embodiments, the processes of FIG. 8 through FIG. 21 are performed on the structure of FIG. 23, so to form the semiconductor structure SP1′. In some embodiments, as shown in FIG. 28 in conjunction with FIG. 29 through FIG. 32, due to the seed layer 510 and the conductive portion 520 (continuously extending from the substrate 200 (e.g., inside OP2b) to the substrate 100 (e.g., inside OP2a)), the bonding strength between the substrate 200 and the substrate 100 can be enhanced and the stress at the interface of the substrate 200 and the substrate 100 inside the openings OP2 can be suppressed, thereby avoiding potential internal cracks of the substate 10 included in the glass core substrate.

In the above embodiments, the substrate 200 includes a single layer structure. However, the disclosure is not limited thereto; alternatively, the substrate 200 may include a multi-layer structure (e.g., two or more than two sub-layers), see the semiconductor structure SP2 of FIG. 40, the semiconductor structure SP2′ of FIG. 50, the semiconductor structure SP3 of FIG. 55, the semiconductor structure SP3′ of FIG. 56, the semiconductor structure SP4 of FIG. 57, and the semiconductor structure SP4′ of FIG. 58.

Referring to FIG. 33, in some embodiments, a substrate 201 and a substrate 202 are provided, where each of the substrates 201 and 202 has a surface S200 and a surface S200b opposite to the surface S200 along the direction Z. The details and materials of the substrates 201 and 202 are similar to or identical to the details of the substrate 20 previous described in FIG. 1, and thus are not repeated herein for brevity. The material of the substrate 201 may be the same as the material of the substrate 202. Alternatively, the material of the substrate 201 may be different from the material of the substrate 202. The disclosure is not limited thereto; the materials of the substrates 201, 202 may be selected and designated based on the demand and design requirements (e.g., tuning the CTE of the substrate 10 so to suppress the warpage of the semiconductor structure of the disclosure).

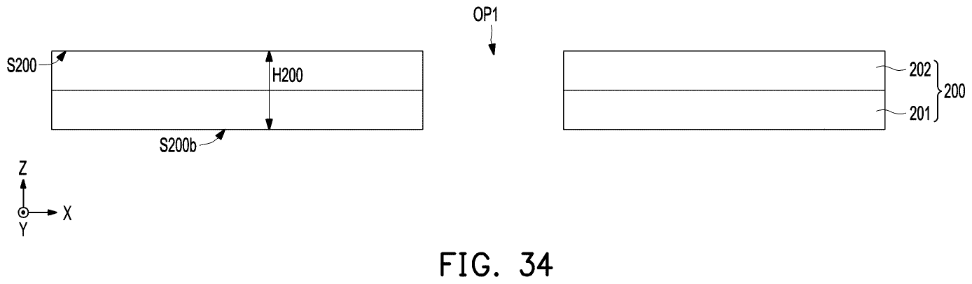

Referring to FIG. 34, in some embodiments, the substrate 202 is bonded to the substrate 201 to form the substrate 200 having a thickness H200. The bonding process of the substrates 201 and 202 is similar to or substantially identical to the bonding process of the substrates 100 and 200 previously described in FIG. 3 and FIG. 4, and thus are not repeated herein. Thereafter, one or more through opening holes OP1 are formed in the substrate 200 including a multi-layer structure (e.g., 201 and 202). Although only one through opening hole OP1 is shown in FIGS. 34-37 and FIG. 40 and only two through opening holes OP1 are shown in FIG. 58, a number of the through opening hole OP1 is not limited in the disclosure. As shown in FIG. 34, the through opening hole OP1 penetrates through the substrates 201 and 202 of the substrate 200. The details and formation of the through opening hole OP1 have been previously described in FIG. 2, and thus are not repeated herein.

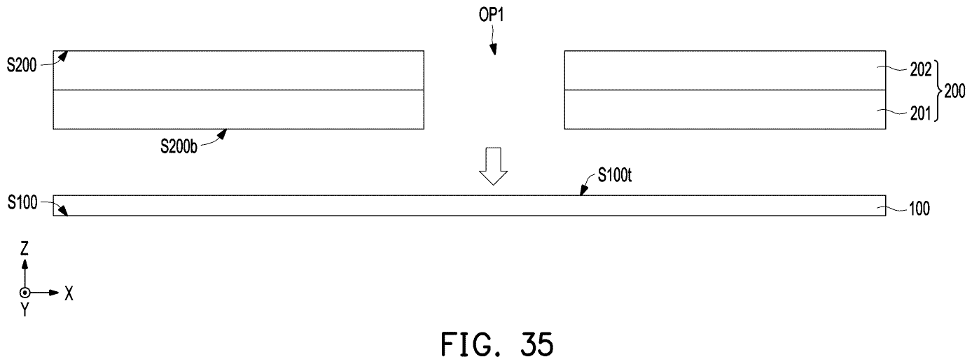

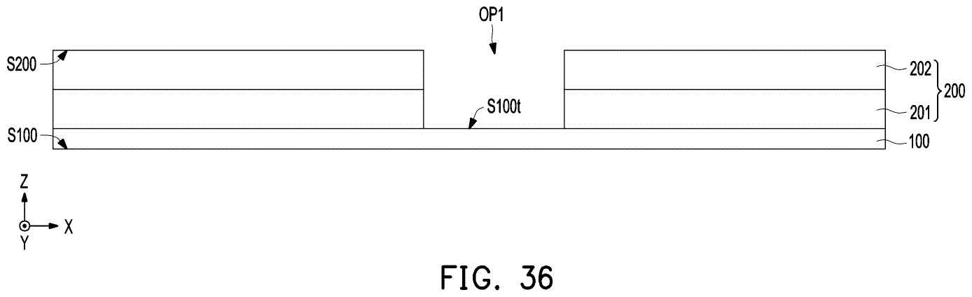

Referring to FIG. 35 and FIG. 36, in some embodiments, the substrate 200 including the multi-layer structure (e.g., 201 and 202) is placed over and bonded to the substrate 100 to form the substrate 10, where a portion of the surface S100t of the substrate 100 is accessibly revealed by the through opening hole OP1. The details of the substrate 10 and the substrate 100 is previously described in FIG. 3, and the bonding of the substrate 200 including the multi-layer structure (e.g., 201 and 202) and the substrate 100 is similar to or substantially identical to the bonding process of the substrates 100 and 200 previously described in FIG. 3 and FIG. 4, and thus are not repeated herein. Due to the configuration of the substrate 10 (including the through opening holes only in the substrate 200 including the multi-layer structure (e.g., 201 and 202)), one or more semiconductor devices 300 can be easily integrated into the substrate 10 without cracks in the substrate 10.

Referring to FIG. 37, in some embodiments, a plurality of openings OP2 are formed in the substrate 10. The formation of openings OP5 have been previously described in FIG. 5, and thus are not repeated herein. As shown in FIG. 37 and FIG. 38, in some embodiments, the sidewalls of the opening OP2 are vertical sidewalls that continuously extend from the surface S200 of the substrate 200 including the multi-layer structure (e.g., 201 and 202) to the surface S100 of the substrate 100. In some alternative embodiments, the sidewalls of the opening OP2 are slant sidewalls that continuously extend from the surface S200 of the substrate 200 including the multi-layer structure (e.g., 201 and 202) to the surface S100 of the substrate 100, see FIG. 39. The disclosure is not limited thereto.

Referring to FIG. 40, in some embodiments, the processes of FIG. 8 through FIG. 21 are performed on the structure of FIG. 37, so to form the semiconductor structure SP2. In some embodiments, as shown in FIG. 40 in conjunction with FIG. 41 through FIG. 42, due to the seed layer 510 and the conductive portion 520 (continuously extending from the substrate 200 including the multi-layer structure (e.g., 201 and 202) to the substrate 100), the bonding strength between the substrate 200 including the multi-layer structure (e.g., 201 and 202) and the substrate 100 can be enhanced and the stress at the interface of the substrate 200 including the multi-layer structure (e.g., 201 and 202) and the substrate 100 inside the openings OP2 can be suppressed, thereby avoiding potential internal cracks of the substate 10 included in the glass core substrate.

In the above embodiments, the openings OP2 are formed in the substrate 200 including the multi-layer structure (e.g., 201 and 202) and substrate 100 of the substrate 10 in a single patterning process (see the process of FIG. 37), however, the disclosure is not limited thereto. In alternatively embodiments, the substrate 100 is patterned to form a plurality of openings OP2a in a first patterning process (see FIG. 43), the substrate 200 including the multi-layer structure (e.g., 201 and 202) is patterned form a plurality of openings OP2b in a second patterning process (see FIG. 43), and then the substrate 200 including the multi-layer structure (e.g., 201 and 202) is bonded to the substrate 100 (see FIG. 44). The first and second patterning processes may be similar to or substantially identical to the patterning process previously described in FIG. 5, and the bonding process may be similar to or substantially identical to the bonding process previously described in FIG. 3 and FIG. 4; and thus, are not repeated herein. As shown in FIG. 44, in the cross-section, the openings OP2a formed in the substrate 100 are at least partially overlapped with the openings OP2b formed in the substrate 200 including the multi-layer structure (e.g., 201 and 202), where the openings OP2a formed in the substrate 100 and the openings OP2b formed in the substrate 200 including the multi-layer structure (e.g., 201 and 202) are spatially communicated to each other so to form a plurality of openings OP2.

In some embodiments, the through opening holes OP1 and the openings OP2 are formed in same process. Alternatively, the through opening holes OP1 and the openings OP2 may be formed in different processes. Due to the configuration of the substrate 10 (including the through opening holes only in the substrate 200), one or more semiconductor devices 300 can be easily integrated into the substrate 10 without cracks in the substrate 10.

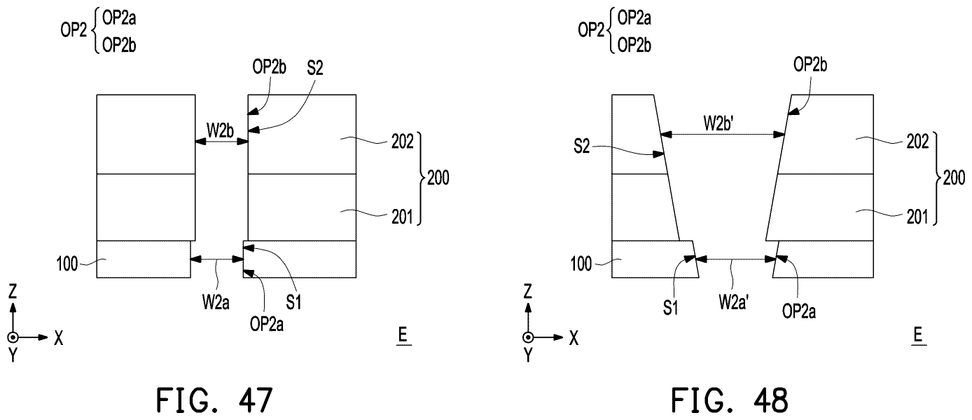

Referring to FIG. 44 and FIG. 45, sidewalls (e.g., S1) the opening OP2a include vertical sidewalls, and sidewalls (e.g., S2) the opening OP2b include vertical sidewalls. In some alternative embodiments, the sidewalls (e.g., S1) the opening OP2a include slant sidewalls, and the sidewalls (e.g., S2) the opening OP2b include slant sidewalls, see FIG. 46. The disclosure is not limited thereto. As shown in FIG. 45 and FIG. 46, a lateral size W2a of one opening OP2a is less than a lateral size W2b of a respective one opening OP2b, where an offset is between the sidewall S2 of the OP2b and the sidewall S1 of the OP2a. Or, the lateral size W2a of one opening OP2a is greater than the lateral size W2b of a respective one opening OP2b, where an offset is between the sidewall S2 of the OP2b and the sidewall S1 of the OP2a. In some embodiments, the lateral size W2a of one opening OP2a is substantially equal to the lateral size W2b of a respective one opening OP2b, where an offset is between the sidewall S2 of the OP2b and the sidewall S1 of the OP2a due to misalignment, see FIG. 47. The disclosure is not limited thereto. Alternatively, the lateral size W2a of one opening OP2a may be substantially equal to the lateral size W2b of a respective one opening OP2b, where there is no offset between the sidewall S2 of the OP2b and the sidewall S1 of the OP2a, similar to the configuration shown in FIG. 38. In some embodiments, the maximum lateral size W2a of one opening OP2a is substantially equal to the minimum lateral size W2b of a respective one opening OP2b, where an offset is between the sidewall S2 of the OP2b and the sidewall S1 of the OP2a due to misalignment, see FIG. 48. The disclosure is not limited thereto. Alternatively, the maximum lateral size W2a of one opening OP2a may be substantially equal to the minimum lateral size W2b of a respective one opening OP2b, where there is no offset between the sidewall S2 of the OP2b and the sidewall S1 of the OP2a, similar to FIG. 39.

Referring to FIG. 49, in some embodiments, the processes of FIG. 8 through FIG. 21 are performed on the structure of FIG. 44, so to form the semiconductor structure SP2′. In some embodiments, as shown in FIG. 49 in conjunction with FIG. 50 through FIG. 53, due to the seed layer 510 and the conductive portion 520 (continuously extending from the substrate 200 including the multi-layer structure (e.g., inside OP2b) to the substrate 100 (e.g., inside OP2a)), the bonding strength between the substrate 200 including the multi-layer structure (e.g., 201 and 202) and the substrate 100 can be enhanced and the stress at the interface of the substrate 200 and the substrate 100 inside the openings OP2 can be suppressed, thereby avoiding potential internal cracks of the substate 10 included in the glass core substrate.

It is appreciated that the number of sub-layers included in the substrate 200 may be more than two, see the semiconductor structure SP3 of FIG. 54 and the semiconductor structure SP3′ of FIG. 55. The semiconductor structure SP3 of FIG. 54 is similar to the semiconductor structure SP2 of FIG. 40 and the semiconductor structure SP3′ of FIG. 55 is similar to the semiconductor structure SP2′ of FIG. 49, a difference is that, in the semiconductor structures SP3 and SP3′, the substrate 200 has a multi-layer structure of three or more sub-layers (e.g., three or more than three substrates). For example, the substrate 200 has a multi-layer structure, where the multi-layer structure includes a substrate 201, . . . , and a substrate 20N, where N greater than or equal to three, as shown in FIG. 54 and FIG. 55. The materials of each of the substrates 201 through 20N may be similar to or substantially identical to the material of the substrate 200 previously described in FIG. 1, and thus are not repeated herein. The materials of the substrates 201 through 20N may be independently selected and designated based on the demand and design requirements (e.g., tuning the CTE of the substrate 10 so to suppress the warpage of the semiconductor structure of the disclosure). The bonding process (e.g., between two adjacent substrates included in the substrate 200) may be similar to or substantially identical to the bonding process previously described in FIG. 33 and FIG. 34, and thus are not repeated herein. The substrates 201, 202, . . . , 20N may be referred to as sub-layers of the substrate 200, and the substrates 100 and 200 may be referred to as sub-layers of the substrate 10.

In the above embodiments of the semiconductor structures SP2, SP2′, SP3 and SP3′, the sub-layers included in the substrate 200 are patterned in a single patterning process, however the disclosure is not limited thereto. Alternatively, the sub-layers included in the substrate 200 may be patterned in different patterning processes to form different groups of openings in each sub-layer of the substrate 200; and after bonding, the different groups of openings formed in different sub-layers of the substrate 200 may be at least partially overlapped with each other (e.g., in the cross sectional view along the direction Z) and thus spatially communicated to each other to form the openings OP2 with the lateral size D3 (e.g., in the top or plane view, such as the X-Y plane). In such cases, the seed layer 510 and the conductive portion 520 may still continuously extending from the sub-layers of the substrate 200 including the multi-layer structure to the substrate 100, the bonding strengths between the sub-layers of the substrate 200 and between the substrate 200 including the multi-layer structure and the substrate 100 can be enhanced and the stresses at the interfaces of the sub-layers of the substrate 200 and the interface of the substrate 200 and the substrate 100 can be suppressed, thereby avoiding potential internal cracks of the substate 10 included in the glass core substrate.

On the other hand, in the above embodiments of the semiconductor structures SP2, SP2′, SP3 and SP3′, the sub-layers included in the substrate 200 are patterned in a single patterning process to form the through opening holes OP1, however the disclosure is not limited thereto. Alternatively, the sub-layers included in the substrate 200 may be patterned in different patterning processes to form different groups of through opening holes in each sub-layer of the substrate 200; and after bonding, the different groups of through opening holes formed in different sub-layers of the substrate 200 may be overlapped with each other (e.g., in the cross-sectional view along the direction Z) and thus spatially communicated to each other to form the through opening holes OP1.

In the above embodiments of the disclosure, only semiconductor devices 300 (with same thickness) are integrated into the substrate 10, however the disclosure is not limited thereto. Alternatively, a plurality of semiconductor devices with different thickness (as measured in the direction Z) are integrated into the substrate 10. For example, the semiconductor structure SP4 of FIG. 56 is similar to the semiconductor structure SP2 of FIG. 40 and the semiconductor structure SP4′ of FIG. 57 is similar to the semiconductor structure SP2′ of FIG. 49, a difference is that, in the semiconductor structures SP4 and SP4′, a semiconductor device 300 with a thickness H1 and a semiconductor device 300A with a thickness H2 may be integrated into the substrate 200 has a multi-layer structure (e.g., 201 and 202), where the thickness H1 is different from the thickness H2.

As shown in FIG. 56 and FIG. 57, only one semiconductor device 300 and only one semiconductor device 300A are shown for illustrative purposes, however the number of the semiconductor device 300 and the number of the semiconductor device 300A may independently be one, two, three or more, which may be selected and designated based on the demand and design requirements. In some embodiments, in the cross-section (e.g., as shown in FIG. 56 and FIG. 57), a through opening hole OP1 is formed in the substrate 201 and the substrate 202 of the substrate 200 for accommodating the semiconductor device 300, and a through opening hole OP3 is formed in the substrate 202 of the substrate 200 for accommodating the semiconductor device 300A. For example, the semiconductor device 300 is adhered to the substrate 10 (e.g., the surface S100t of the substrate 100 exposed by the through opening hole OP1 and at least a part of the sidewall of the through opening hole OP1) through the adhesive 400 and the semiconductor device 300A is adhered to the substrate 10 (e.g., the surface S200 of the substrate 201 exposed by the through opening hole OP3 and at least a part of the sidewall of the through opening hole OP3) through the adhesive 400A. The details and material of the adhesive 400A is similar to or substantially identical to the details of the adhesive 400 previously described, the details and formation of the through opening hole OP3 is similar to the details and formation of the through opening hole OP1 previously described, and thus are not repeated herein for brevity. As shown in FIG. 59, the through opening hole OP3 is laterally arranged to the through opening holes OP1, for example. That is to say, the through opening hole OP3 is not overlapped with the through opening holes OP1, in the cross-sectional view. In some embodiments, a distance (not label) between two adjacent the through opening holes OP1 and OP3 is greater than or substantially equal to the distance D1 or D2.

For example, the adhesive 400 extends on a rear side RS of the semiconductor device 300 and further extends onto the sidewalls of the semiconductor device 300, where the adhesive 400 at least does not fill up a space (e.g., G in FIG. 56/FIG. 57) of the through opening hole OP1 disposed between the semiconductor device 300 and the substrate 200. In other words, the space G is in the through opening hole OP1 disposed between the semiconductor device 300 and the substrate 200, after integrating the semiconductor device 300 into the substrate 10 by the adhesive 400. In such case, the rear side RS of the semiconductor device 300 is completely covered by the adhesive 400, and the sidewalls of the semiconductor device 300 and the sidewall of the through opening hole OP1 are partially covered by the adhesive 400. The adhesive 400 may have a convex top surface in relative to the surface S200 of the substrate 202 included in of the substrate 200, see FIG. 56 and FIG. 9. However, the disclosure is not limited thereto; alternatively, the adhesive 400 may have a concave top surface in relative to the surface S200 of the substrate 202 included in the substrate 200, see FIG. 56 and FIG. 10. Or, the adhesive 400 may have a substantially planar top surface in relative to the surface S200 of the substrate 202 included in the substrate 200, see FIG. 56 and FIG. 11. In some embodiments, the illustrated top surface of the adhesive 400 is lower than the surface S200 of the substrate 200 and the active side AS of the semiconductor device 300. Owing to such configuration, the active surface AS of the semiconductor device 300 and the surface S200 of the substrate 200 would not be contaminated by the adhesive 400.

For example, the adhesive 400A extends on a rear side RS of the semiconductor device 300A and further extends onto the sidewalls of the semiconductor device 300A, where the adhesive 400A at least does not fill up a space (e.g., G in FIG. 56/FIG. 57) of the through opening hole OP3 disposed between the semiconductor device 300A and the substrate 202 of the substrate 200. In other words, the space G is in the through opening hole OP3 disposed between the semiconductor device 300A and the substrate 202 of the substrate 200, after integrating the semiconductor device 300A into the substrate 10 by the adhesive 400A. In such case, the rear side RS of the semiconductor device 300A is completely covered by the adhesive 400A, and the sidewalls of the semiconductor device 300A and the sidewall of the through opening hole OP3 are partially covered by the adhesive 400A. The adhesive 400A may have a convex top surface in relative to the surface S200 of the substrate 202 included in the substrate 200, similar to FIG. 9. However, the disclosure is not limited thereto; alternatively, the adhesive 400A may have a concave top surface in relative to the surface S200 of the substrate 202 included in the substrate 200, similar to FIG. 10. Or, the adhesive 400A may have a substantially planar top surface in relative to the surface S200 of the substrate 202 included in the substrate 200, similar to FIG. 11. In some embodiments, the illustrated top surface of the adhesive 400A is lower than the surface S200 of the substrate 202 included in the substrate 200 and the active side AS of the semiconductor device 300A. Owing to such configuration, the active surface AS of the semiconductor device 300A and the surface S200 of the substrate 202 included in the substrate 200 would not be contaminated by the adhesive 400A.

The details of the semiconductor device(s) 300 have been previously discussed in FIG. 8, and thus are not repeated herein. In some embodiments, the semiconductor device(s) 300A may, independently, include an integrated passives die (IPD). In addition, the semiconductor device(s) 300A may further, independently, include one or more functions of an electrical and/or optical I/O interface die, an IPD, a VR die, a LSI die with or without DTC features, a LSI die with multi-tier functions such as electrical and/or optical network circuit interfaces, IPD, VR, DTC, or the like. The types of the semiconductor device(s) 300A may be selected and designated based on the demand and design requirements, and thus are not specifically limited in the disclosure. For example, the semiconductor device(s) 300A includes IPDs. As shown in FIG. 56 and FIG. 57, for example, the semiconductor device 300A includes a plurality of conductive pads 310 distributed on the active side AS of the semiconductor device 300A for electrical connections to later-formed components (e.g., 500p1 and/or 800). The types of the semiconductor devices 300 and 300A may be different. Alternatively, the types of the semiconductor devices 300 and 300A may be similar to or substantially identical to each other, the disclosure is not limited thereto. Due to the configuration of the substrate 10 (including different through opening holes (e.g., OP1 only in and penetrating through the entire of the substrate 200 and OP3 only in the substate 200 and only penetrating through the substrate 202)), one or more semiconductor devices (e.g., 300 and 300A) with different thicknesses can be easily integrated into the substrate 10 without cracks in the substrate 10.

Similar modification may also be adopted by the semiconductor structures SP3 and SP3′ to include semiconductor devices with different thicknesses (e.g., includes three or more different thicknesses) by forming different through opening holes in the sub-layers of the substrate 200, where the through opening holes may completely penetrating through one or more than one sub-layer of the substrate 200 and does not stop at a position inside one sub-layer of the substrate 200.

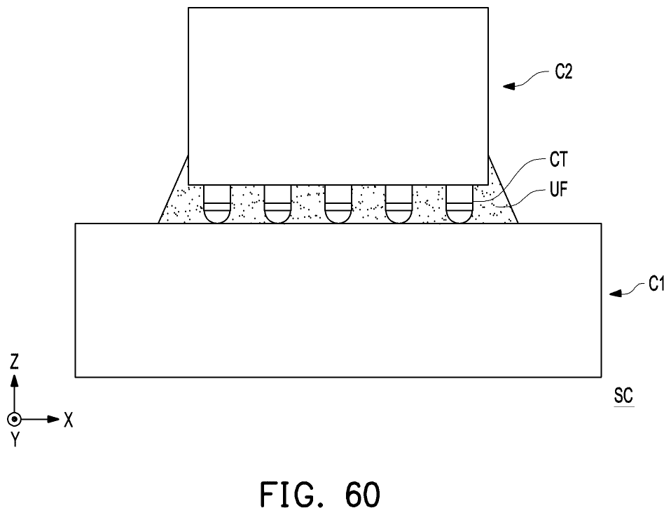

Due to the semiconductor devices 300 and/or 300A, the performance of the semiconductor structures (e.g., SP1, SP1′, SP2, SP2′, SP3, SP3′, SP4, SP4′ and their modifications) may be further improved. The semiconductor structures SP1, SP1′, SP2, SP2′, SP3, SP3′, SP4, SP4′ and their modifications may be further mounted onto another external/additional electronical component, for example, mounted onto a circuit structure, such as a motherboard, a package substrate, another printed circuit board (PCB), a printed wiring board, and/or other carrier that is capable of carrying integrated circuits. FIG. 60 is a schematic cross-sectional view of an application of a semiconductor structure in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 60, in some embodiments, a component assembly SC including a first component C1 and a second component C2 disposed over the first component C1 is provided. The first component C1 may be or may include a circuit structure, such as a motherboard, a package substrate, another PCB, a printed wiring board, an interposer, and/or other carrier that is capable of carrying integrated circuits. In some embodiments, the second component C2 mounted on the first component C1 is similar to one of the semiconductor structures SP1, SP1′, SP2, SP2′, SP3, SP3′, SP4, SP4′ and their modifications. In a non-limiting example, one or more semiconductor structure (e.g., one or multiple semiconductor structures SP1, SP1′, SP2, SP2′, SP3, SP3′, SP4, SP4′ and their modifications) may be electrically coupled to the first component C1 through a plurality of terminals CT. The terminals CT may be the conductive terminals 4000 as previously described.

In some embodiments, an underfill UF is formed between the gap of the first component C1 and the second component C2 to at least laterally cover the terminals CT. Alternatively, the underfill UF is omitted. The underfill UF may be any acceptable material, such as a polymer, epoxy resin, molding underfill, or the like, for example. In one embodiment, the underfill may be formed by underfill dispensing, a capillary flow process, or any other suitable method. Owing to the underfill UF, a bonding strength between the first component C1 and the second component C2 is enhanced.

In accordance with some embodiments, a semiconductor structure includes a substrate, a semiconductor device, a plurality of conductive pillars, a first redistribution circuit structure, and a semiconductor die. The substrate includes a first sub-layer and a second sub-layer disposed thereon. The semiconductor device is disposed in the second sub-layer and over the first sub-layer. The plurality of conductive pillars penetrate through the substrate and is next to the semiconductor device. The first redistribution circuit structure is disposed over the substrate and electrically coupled to the semiconductor device and the plurality of conductive pillars. The semiconductor die is disposed over and electrically coupled to the first redistribution circuit structure and electrically coupled to the semiconductor device through the first redistribution circuit structure, where the first redistribution circuit structure is disposed between the semiconductor die and the substrate.

In accordance with some embodiments, a semiconductor structure includes a glass-based substrate, a first semiconductor device and a second semiconductor device, a first redistribution circuit structure, and a semiconductor die. The glass-based substrate includes a base substrate and a stacking substrate disposed over the base substrate, where the stacking substrate has a plurality of sub-layers stacked on each other. The first semiconductor device and the second semiconductor device are disposed in the stacking substrate, where a first distance between the first semiconductor device and the base substrate is different from a second distance between the second semiconductor device and the base substrate. The first redistribution circuit structure is disposed over the glass-based substrate and electrically coupled to the first semiconductor device and the second semiconductor device. The semiconductor die is disposed over and electrically coupled to the first redistribution circuit structure and electrically coupled to the first semiconductor device and the second semiconductor device through the first redistribution circuit structure, where the first redistribution circuit structure is disposed between the semiconductor die and the glass-based substrate.

In accordance with some embodiments, a method of manufacturing a semiconductor structure includes the following steps: providing a first substrate; providing a second substrate with a through opening hole penetrating therethrough; bonding the second substrate to the first substrate to form a substrate, where a portion of a surface of the first substrate is accessibly revealed by the through opening hole; forming a plurality of openings in the substrate, the plurality of openings extending from the first substrate to the second substrate; disposing a semiconductor device in the through opening hole over the portion of the surface of the first substrate accessibly revealed by the through opening hole; forming a plurality of conductive pillars in the plurality of openings, respectively; forming a first distribution circuit structure and a second distribution circuit structure at two opposite sides of the substrate, the first distribution circuit structure being electrically coupled to the second distribution circuit structure through the plurality of conductive pillars; disposing a semiconductor die over the first distribution circuit structure; and disposing a plurality of conductive terminals over the second distribution circuit structure.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor structure, comprising:
a substrate, comprising a first sub-layer and a second sub-layer disposed thereon;
a semiconductor device, disposed in the second sub-layer and over the first sub-layer;
a plurality of conductive pillars, penetrating through the substrate and next to the semiconductor device;
a first redistribution circuit structure, disposed over the substrate and electrically coupled to the semiconductor device and the plurality of conductive pillars; and
a semiconductor die, disposed over and electrically coupled to the first redistribution circuit structure and electrically coupled to the semiconductor device through the first redistribution circuit structure, wherein the first redistribution circuit structure is disposed between the semiconductor die and the substrate.

2. The semiconductor structure of claim 1, further comprising:
a second redistribution circuit structure, disposed over the substrate and electrically coupled to the plurality of conductive pillars, wherein the substrate is disposed between the first redistribution circuit structure and the second redistribution circuit structure, and the first redistribution circuit structure and the second redistribution circuit structure are electrically coupled to each other through the plurality of conductive pillars.

3. The semiconductor structure of claim 2, further comprising:
a plurality of conductive terminals, connected to and electrically coupled to the second redistribution circuit structure, the second redistribution circuit structure is disposed between the substrate and the plurality of conductive terminals.

4. The semiconductor structure of claim 1, wherein the second sub-layer is disposed between the first redistribution circuit structure and the first sub-layer, and the semiconductor device is disposed inside a through opening hole penetrating the second sub-layer.

5. The semiconductor structure of claim 4, wherein in a stacking direction of the first sub-layer and the second sub-layer, a thickness of the through opening hole is equal to a thickness of the second sub-layer.

6. The semiconductor structure of claim 1, wherein the second sub-layer is disposed between the first redistribution circuit structure and the first sub-layer, and the plurality of conductive pillars are respectively disposed inside a plurality of openings penetrating the substrate.

7. The semiconductor structure of claim 6, wherein in a stacking direction of the first sub-layer and the second sub-layer, a thickness of the plurality of openings is equal to a sum of a thickness of the second sub-layer and a thickness of the first sub-layer.

8. The semiconductor structure of claim 6, wherein the plurality of conductive pillars are continuously extended inside the plurality of openings and cover an interface of the first sub-layer and the second sub-layer.

9. A semiconductor structure, comprising:
a glass-based substrate, comprising:
a base substrate; and
a stacking substrate, disposed over the base substrate, wherein the stacking substrate has a plurality of sub-layers stacked on each other;
a first semiconductor device and a second semiconductor device, disposed in the stacking substrate, wherein a first distance between the first semiconductor device and the base substrate is different from a second distance between the second semiconductor device and the base substrate;
a first redistribution circuit structure, disposed over the glass-based substrate and electrically coupled to the first semiconductor device and the second semiconductor device; and
a semiconductor die, disposed over and electrically coupled to the first redistribution circuit structure and electrically coupled to the first semiconductor device and the second semiconductor device through the first redistribution circuit structure, wherein the first redistribution circuit structure is disposed between the semiconductor die and the glass-based substrate.

10. The semiconductor structure of claim 9, wherein a first active side of the first semiconductor device is closer to an outermost surface of the stacking substrate than a first rear side of the first semiconductor device, and a second active side of the second semiconductor device is closer to the outermost surface of the stacking substrate than a second rear side of the second semiconductor device.

11. The semiconductor structure of claim 9, further comprising:
a plurality of conductive pillars, penetrating the glass-based substrate and electrically coupled to the first redistribution circuit structure, wherein in a cross-section, sidewalls of the plurality of conductive pillars are planar sidewalls.

12. The semiconductor structure of claim 9, further comprising:
a plurality of conductive pillars, penetrating the glass-based substrate and electrically coupled to the first redistribution circuit structure, wherein in a cross-section, sidewalls of the plurality of conductive pillars are non-planar sidewalls.

13. The semiconductor structure of claim 9,
wherein the first semiconductor device is disposed in a first through opening hole formed in the stacking substrate, and the first through opening hole completely penetrates through a first group of sub-layers included in the plurality of sub-layers,
wherein the second semiconductor device is disposed in a second through opening hole formed in the stacking substrate, and the second through opening hole completely penetrates through a second group of sub-layers included in the plurality of sub-layers,
wherein a number of the first group of the sub-layers is different than a number of the second group of the sub-layers, and
wherein in a stacking direction of the base substrate and the stacking substrate, a thickness of the first through opening hole is a sum of thicknesses of the first group of the sub-layers, and a thickness of the second through opening hole is a sum of thicknesses of the second group of the sub-layers.

14. The semiconductor structure of claim 9, further comprising:
a second redistribution circuit structure, disposed over the glass-based substrate, wherein the glass-based substrate is disposed between the first redistribution circuit structure and the second redistribution circuit structure;
a plurality of conductive pillars, penetrating the glass-based substrate and electrically coupling the first redistribution circuit structure and the second redistribution circuit structure; and
a plurality of conductive terminals, connected to and electrically coupled to the second redistribution circuit structure, the second redistribution circuit structure is disposed between the plurality of conductive terminals and the glass-based substrate.

15. The semiconductor structure of claim 9, wherein a material of the base substrate is different from at least one sub-layer of the plurality of sub-layers.

16. The semiconductor structure of claim 9, wherein a material of at least one sub-layer of the plurality of sub-layers is different from another one sub-layer of the plurality of sub-layers.

17. A method of manufacturing a semiconductor structure, comprising:
providing a first substrate;
providing a second substrate with a through opening hole penetrating therethrough;
bonding the second substrate to the first substrate to form a substrate, wherein a portion of a surface of the first substrate is accessibly revealed by the through opening hole;
forming a plurality of openings in the substrate, the plurality of openings extending from the first substrate to the second substrate;
disposing a semiconductor device in the through opening hole over the portion of the surface of the first substrate accessibly revealed by the through opening hole;
forming a plurality of conductive pillars in the plurality of openings, respectively;
forming a first distribution circuit structure and a second distribution circuit structure at two opposite sides of the substrate, the first distribution circuit structure being electrically coupled to the second distribution circuit structure through the plurality of conductive pillars;
disposing a semiconductor die over the first distribution circuit structure; and
disposing a plurality of conductive terminals over the second distribution circuit structure.

18. The method of claim 17, wherein:
forming the plurality of openings in the substrate comprises performing a single patterning process onto the first substrate and the second substrate so to form the plurality of openings.

19. The method of claim 17, wherein:
providing the first substrate comprises the first substrate with a plurality of first openings penetrating therethrough;
providing the second substrate with the through opening hole penetrating therethrough comprises providing the second substrate with the through opening hole penetrating therethrough and a plurality of second openings penetrating therethrough; and
forming the plurality of openings in the substrate comprises spatially communicating the plurality of first openings to the plurality of second openings in a one-to-one configuration during bonding the second substrate to the first substrate, so to form the plurality of openings penetrating the substrate.

20. The method of claim 17, wherein the second substrate comprises a plurality of sub-layers.
